(19) United States
(12) Patent Application Publication
(10) Pub. No.: US 2016/0118337 A1
(43) Pub. Date: Apr. 28, 2016

(54) EMBEDDED PACKAGES, METHODS OF FABRICATING THE SAME, ELECTRONIC SYSTEMS INCLUDING THE SAME, AND MEMORY CARDS INCLUDING THE SAME

(71) Applicant: SK hynix Inc., Icheon-si Gyeonggi-do (KR)

(72) Inventors: Sang Hoon YOON, Icheon-si Gyeonggi-do (KR); Ki Il MOON, Seoul (KR); Myoung Seob KIM, Icheon-si Gyeonggi-do (KR); Yun Mi SONG, Seoul (KR)

(21) Appl. No.: 14/717,624

(22) Filed: May 20, 2015

(30) Foreign Application Priority Data
Oct. 23, 2014 (KR) 10-2014-0144245

(51) Int. Cl. H01L 23/522; H01L 23/31; H01L 23/532

(52) U.S. Cl. CPC H01L 23/5226; H01L 23/53238; H01L 23/3114

(57) ABSTRACT

An embedded package includes a chip having a top surface on which a connection member is disposed, a first insulation layer surrounding a portion of the chip, a second insulation layer disposed on the first insulation layer to cover the chip, circuit patterns disposed on a bottom surface of the first insulation layer, a third insulation layer disposed on the bottom surface of the first insulation layer to cover the circuit patterns, an external connection terminal penetrating the third insulation layer to contact any one of the circuit patterns, a metal layer disposed on a top surface of the second insulation layer, a first via penetrating the first insulation layer to electrically couple the connection member to any one of the circuit patterns, and a second via penetrating the first and second insulation layers to electrically couple the metal layer to any one of the circuit patterns.

### CROSS-REFERENCE TO RELATED APPLICATION

The present application claims priority under 35 U.S.C 119(a) to Korean Patent Application No. 10-2014-0144245, filed on Oct. 23, 2014, in the Korean Intellectual Property Office, which is incorporated herein by reference in its entirety.

### BACKGROUND

1. Technical Field

Embodiments of the invention relate to semiconductor packages and, more particularly, to embedded packages, methods of fabricating the same, electronic systems including the same, and memory cards including the same.

2. Related Art

As portable electronic systems become abruptly scaled down, spaces that semiconductor packages occupy in the portable electronic systems have been reduced. Thus, attempts to reduce the sizes of the semiconductor packages have been continuously made with the development of smaller electronic systems. In response to such a trend, embedded package techniques have been proposed to minimize the size of the semiconductor packages. According to the embedded package techniques, a semiconductor chip is not mounted on a surface of a package substrate. That is, the semiconductor chip of the embedded package may be embedded in the package substrate. Thus, the embedded package techniques may be advantageous in fabrication of small-sized packages. Further, since the chip of the embedded package is embedded in the package substrate, length of interconnection lines for electrically connecting the chip to the package substrate can be reduced to improve the drivability of the embedded package.

### SUMMARY

According to an embodiment, an embedded package includes a chip having a top surface on which a connection member is disposed. The embedded package also includes a first insulation layer surrounding a portion of the chip, a second insulation layer disposed on the first insulation layer so that a bottom surface of the second insulation layer contacts a top surface of the first insulation layer and the second insulation layer covers the chip. The embedded package also includes a plurality of circuit patterns disposed on a bottom surface of the first insulation layer, a third insulation layer disposed on the bottom surface of the first insulation layer to cover the plurality of circuit patterns, and an external connection terminal penetrating the third insulation layer to contact any one of the plurality of circuit patterns. The embedded package also includes a metal layer disposed on a top surface of the second insulation layer, a first via penetrating the first insulation layer to electrically couple the connection member to any one of the circuit patterns. The embedded package also includes a second via penetrating the first and second insulation layers to electrically couple the metal layer to any one of the circuit patterns.

According to an embodiment, an embedded package includes a chip having a top surface on which connection members are disposed, a first insulation layer surrounding a portion of the chip, and a second insulation layer disposed on the first insulation layer so that a bottom surface of the second insulation layer contacts a top surface of the first insulation layer and the second insulation layer covers the chip. An embedded package also includes a plurality of circuit patterns disposed on a bottom surface of the first insulation layer, a third insulation layer disposed on the bottom surface of the first insulation layer to cover the plurality of circuit patterns, and an external connection terminal penetrating the third insulation layer to contact any one of the plurality of circuit patterns. The embedded package also includes a metal layer disposed on a top surface of the second insulation layer, first vias penetrating the first insulation layer to electrically couple the connection members to the circuit patterns, and second vias penetrating the first and second insulation layers to electrically couple the metal layer to the circuit patterns. Further, distances between the second vias and the chip are different.

According to an embodiment, an embedded package includes a first chip having a top surface on which first connection members are disposed and a second chip having a top surface on which second connection members are disposed and having a bottom surface to which a bottom surface of the first chip is attached. The embedded package also includes a first insulation layer surrounding a portion of the first chip, a second insulation layer surrounding a portion of the second chip, and a third insulation layer disposed between the first and second insulation layers. The embedded package also includes a plurality of first circuit patterns disposed on a bottom surface of the first insulation layer, a plurality of second circuit patterns disposed on a top surface of the second insulation layer, and a fourth insulation layer disposed on the bottom surface of the first insulation layer to cover the plurality of first circuit patterns. The embedded package also includes an external connection terminal penetrating the fourth insulation layer to contact any one of the plurality of first circuit patterns, and a fifth insulation layer disposed on the top surface of the second insulation to cover the plurality of second circuit patterns. Further, the embedded package also includes a metal layer disposed on a top surface of the fifth insulation layer and lower vias penetrating the first insulation layer to electrically couple the first connection members to the first circuit patterns. The embedded package also includes upper vias penetrating the second insulation layer to electrically couple the second connection members to the second circuit patterns, and first through electrodes and second through electrodes penetrating the first to third insulation layers to electrically couple the first circuit patterns to the second circuit patterns. The embedded package also includes connection vias penetrating the fifth insulation layer to electrically couple the metal layer to the second circuit patterns.

According to an embodiment, an embedded package includes a first chip having a top surface on which first connection members are disposed and a second chip having a top surface on which second connection members are disposed and having a bottom surface to which a bottom surface of the first chip is attached. The embedded package also includes a first insulation layer surrounding a portion of the first chip, a second insulation layer surrounding a portion of the second chip, and a third insulation layer disposed between the first and second insulation layers. The embedded package also includes a plurality of first circuit patterns disposed on a bottom surface of the first insulation layer, a plurality of second circuit patterns disposed on a top surface of the second insulation layer, and a fourth insulation layer disposed on the bottom surface of the first insulation layer to cover the plurality of first circuit patterns. The embedded package also includes an external connection terminal penetrating the fourth insulation layer to contact any one of the plurality of first circuit patterns and a fifth insulation layer disposed on the top surface of the second insulation to cover the plurality of second circuit patterns. The embedded package also includes a metal layer disposed on a top surface of the fifth insulation layer and lower vias penetrating the first insulation layer to electrically couple the first connection members to the first circuit patterns. The embedded package also includes upper vias penetrating the second insulation layer to electrically couple the second connection members to the second circuit patterns and first through electrodes penetrating the first to third insulation layers to electrically couple the first circuit patterns to the second circuit patterns. Further, the embedded package includes second through electrodes penetrating the first to third insulation layers to electrically couple the first circuit patterns to the second circuit patterns, and connection vias penetrating the fifth insulation layer to electrically couple the metal layer to the second circuit patterns. In addition, distances between the second through electrodes and the first or second chip are different from each other.

According to an embodiment, a method of fabricating an embedded package includes embedding a chip having connection members in a first insulation layer, and attaching a second insulation layer to the first insulation layer to cover the chip. The method also includes patterning the first and second insulation layers to form via holes exposing the connection members and to form through holes penetrating the first and second insulation layers. Further, the method includes filling the via holes and the through holes with a metal material to form first vias in the via holes and to form second vias in the through holes. The method also includes forming a metal layer contacting the second vias on the second insulation layer, and forming a plurality of circuit patterns on a surface of the first insulation layer opposite to the second insulation layer. A first group of the plurality of circuit patterns contacts the second via. A third insulation layer is formed on the first insulation layer and the plurality of circuit patterns. The third insulation layer has an opening that exposes any one of the plurality of circuit patterns. An external connection terminal is formed in the opening.

According to an embodiment, a method of fabricating an embedded package includes providing a first structure including a first insulation layer in which a portion of a first chip having first connection members are embedded. The method also includes providing a second structure including a second insulation layer in which a portion of a second chip having second connection members are embedded. Further, the method includes providing a third structure including a third insulation layer. The first, second and third structures are vertically aligned with each other so that the third structure is disposed between the first and second structures. The first, second and third structures are laminated so that the first and second chips are embedded in the first, second and third structures. The first and second insulation layers are patterned to form lower via holes exposing the first connection members and upper via holes exposing the second connection members. First through holes and second through holes are formed to penetrate the first, second and third insulation layers. The lower via holes, the upper via holes, the first through holes, and the second through holes are filled with a metal material to form lower vias in the lower via holes, upper vias in the upper via holes, first through electrodes in the first through holes, and second through electrodes in the second through holes. A plurality of first circuit patterns are formed on a bottom surface of the first insulation layer opposite to the third insulation layer, and a plurality of second circuit patterns are formed on a top surface of the second insulation layer opposite to the third insulation layer. A fourth insulation layer is formed on the first insulation layer to cover the plurality of first circuit patterns, and a fifth insulation layer is formed on the second insulation layer to cover the plurality of second circuit patterns. The fifth insulation layer is patterned to form via holes exposing a first group of the second circuit patterns. The via holes are filled with a metal material to form connection vias. A metal layer is formed on a top surface of the fifth insulation layer opposite to the second insulation layer. The fourth insulation layer is patterned to form an opening that exposes any one of the plurality of first circuit patterns. An external connection terminal is formed in the opening.

According to an embodiment, an electronic system includes a memory and a controller electrically coupled with the memory through a bus. The memory or the controller includes a chip having a top surface on which a connection member is disposed. The memory or controller also includes a first insulation layer surrounding a portion of the chip, and a second insulation layer disposed on the first insulation layer so that a bottom surface of the second insulation layer contacts a top surface of the first insulation layer and the second insulation layer covers the chip. The memory or controller also includes a plurality of circuit patterns disposed on a bottom surface of the first insulation layer. The memory or controller also includes a third insulation layer disposed on the bottom surface of the first insulation layer to cover the plurality of circuit patterns. Further, the memory or controller also includes an external connection terminal penetrating the third insulation layer to contact any one of the plurality of circuit patterns. The memory or controller also includes a metal layer disposed on a top surface of the second insulation layer, a first via penetrating the first insulation layer to electrically couple the connection member to any one of the circuit patterns, and a second via penetrating the first and second insulation layers to electrically couple the metal layer to any one of the circuit patterns.

According to an embodiment, an electronic system includes a memory and a controller electrically coupled with the memory through a bus. The memory or the controller includes a chip having a top surface on which connection members are disposed. The memory or controller also includes a first insulation layer surrounding a portion of the chip, and a second insulation layer disposed on the first insulation layer so that a bottom surface of the second insulation layer contacts a top surface of the first insulation layer and the second insulation layer covers the chip. The memory or controller also includes a plurality of circuit patterns disposed on a bottom surface of the first insulation layer, and a third insulation layer disposed on the bottom surface of the first insulation layer to cover the plurality of circuit patterns. The memory or controller also includes an external connection terminal penetrating the third insulation layer to contact any one of the plurality of circuit patterns. The memory or controller also includes a metal layer disposed on a top surface of the second insulation layer, first vias penetrating the first insulation layer to electrically couple the connection members to the circuit patterns, and second vias penetrating the first and second insulation layers to electrically couple the metal layer to the circuit patterns. Distances between the second vias and the chip are different.

According to an embodiment, an electronic system includes a memory and a controller electrically coupled with the memory through a bus. The memory or the controller includes a first chip having a top surface on which first connection members are disposed. The memory or controller also includes a second chip having a top surface on which second connection members are disposed and having a bottom surface to which a bottom surface of the first chip is attached. The memory or controller also includes a first insulation layer surrounding a portion of the first chip, a second insulation layer surrounding a portion of the second chip, and a third insulation layer disposed between the first and second insulation layers. The memory or controller also includes a plurality of first circuit patterns disposed on a bottom surface of the first insulation layer, and a plurality of second circuit patterns disposed on a top surface of the second insulation layer. The memory or controller also includes a fourth insulation layer disposed on the bottom surface of the first insulation layer to cover the plurality of first circuit patterns. The memory or controller also includes an external connection terminal penetrating the fourth insulation layer to contact any one of the plurality of first circuit patterns, and a fifth insulation layer disposed on the top surface of the second insulation to cover the plurality of second circuit patterns. The memory or controller also includes a metal layer disposed on a top surface of the fifth insulation layer, and lower vias penetrating the first insulation layer to electrically couple the first connection members to the first circuit patterns. The memory or controller also includes upper vias penetrating the second insulation layer to electrically couple the second connection members to the second circuit patterns. The memory or controller also includes first through electrodes and second through electrodes penetrating the first to third insulation layers to electrically couple the first circuit patterns to the second circuit patterns, and connection vias penetrating the fifth insulation layer to electrically couple the metal layer to the second circuit patterns.

According to an embodiment, an electronic system includes a controller electrically coupled with a memory through a bus. The memory or the controller includes a first chip having a top surface on which first connection members are disposed. The memory or controller also includes a second chip having a top surface on which second connection members are disposed and having a bottom surface to which a bottom surface of the first chip is attached. The memory or controller also includes a first insulation layer surrounding a portion of the first chip, a second insulation layer surrounding a portion of the second chip, and a third insulation layer disposed between the first and second insulation layers. The memory or controller also includes a plurality of first circuit patterns disposed on a bottom surface of the first insulation layer, and a plurality of second circuit patterns disposed on a top surface of the second insulation layer. The memory or controller also includes a fourth insulation layer disposed on the bottom surface of the first insulation layer to cover the plurality of first circuit patterns. The memory or controller also includes an external connection terminal penetrating the fourth insulation layer to contact any one of the plurality of first circuit patterns. The memory or controller also includes a fifth insulation layer disposed on the top surface of the second insulation to cover the plurality of second circuit patterns. The memory or controller also includes a metal layer disposed on a top surface of the fifth insulation layer, and lower vias penetrating the first insulation layer to electrically couple the first connection members to the first circuit patterns. The memory or controller also includes upper vias penetrating the second insulation layer to electrically couple the second connection members to the second circuit patterns. The memory or controller also includes first through electrodes penetrating the first to third insulation layers to electrically couple the first circuit patterns to the second circuit patterns. The memory or controller also includes second through electrodes penetrating the first to third insulation layers to electrically couple the first circuit patterns to the second circuit patterns. The memory or controller also includes connection vias penetrating the fifth insulation layer to electrically couple the metal layer to the second circuit patterns. Distances between the second through electrodes and the first or second chip are different.

According to an embodiment, a memory card includes a memory controller controlling an operation of a memory. The memory includes a chip having a top surface on which a connection member is disposed. The memory also includes a first insulation layer surrounding a portion of the chip, and a second insulation layer disposed on the first insulation layer so that a bottom surface of the second insulation layer contacts a top surface of the first insulation layer and the second insulation layer covers the chip. The memory also includes a plurality of circuit patterns disposed on a bottom surface of the first insulation layer, and a third insulation layer disposed on the bottom surface of the first insulation layer to cover the plurality of circuit patterns. The memory also includes an external connection terminal penetrating the third insulation layer to electrically couple any one of the plurality of circuit patterns. The memory also includes a metal layer disposed on a top surface of the second insulation layer, a first via penetrating the first insulation layer to electrically couple the connection member to any one of the circuit patterns, and a second via penetrating the first and second insulation layers to electrically couple the metal layer to any one of the circuit patterns.

According to an embodiment, a memory card includes a memory controller controlling an operation of a memory component. The memory component includes a chip having a top surface on which connection members are disposed, a first insulation layer surrounding a portion of the chip. The memory component also includes a second insulation layer disposed on the first insulation layer so that a bottom surface of the second insulation layer contacts a top surface of the first insulation layer and the second insulation layer covers the chip. The memory component also includes a plurality of circuit patterns disposed on a bottom surface of the first insulation layer, and a third insulation layer disposed on the bottom surface of the first insulation layer to cover the plurality of circuit patterns. The memory component also includes an external connection terminal penetrating the third insulation layer to contact any one of the plurality of circuit patterns. The memory component also includes a metal layer disposed on a top surface of the second insulation layer. The memory component also includes first vias penetrating the first insulation layer to electrically couple the connection members to the circuit patterns, and second vias penetrating the first and second insulation layers to electrically couple the metal layer to the circuit patterns. Distances between the second vias and the chip are different.

According to an embodiment, a memory card includes a memory controller controlling an operation of a memory component. The memory component includes a first chip having a top surface on which first connection members are disposed. The memory component also includes a second chip having a top surface on which second connection members are disposed and having a bottom surface to which a bottom surface of the first chip is attached. The memory component also includes a first insulation layer surrounding a portion of the first chip, a second insulation layer surrounding a portion of the second chip, and a third insulation layer disposed between the first and second insulation layers. The memory component also includes a plurality of first circuit patterns disposed on a bottom surface of the first insulation layer, and a plurality of second circuit patterns disposed on a top surface of the second insulation layer. The memory component also includes a fourth insulation layer disposed on the bottom surface of the first insulation layer to cover the plurality of first circuit patterns. The memory component also includes an external connection terminal penetrating the fourth insulation layer to contact any one of the plurality of first circuit patterns. The memory component also includes a fifth insulation layer disposed on the top surface of the second insulation to cover the plurality of second circuit patterns. The memory component also includes a metal layer disposed on a top surface of the fifth insulation layer. The memory component also includes lower vias penetrating the first insulation layer to electrically couple the first connection members to the first circuit patterns and upper vias penetrating the second insulation layer to electrically couple the second connection members to the second circuit patterns. The memory component also includes first through electrodes and second through electrodes penetrating the first to third insulation layers to electrically couple the first circuit patterns to the second circuit patterns. The memory component also includes connection vias penetrating the fifth insulation layer to electrically couple the metal layer to the second circuit patterns.

According to an embodiment, a memory card includes a memory controller controlling an operation of a memory component. The memory component includes a first chip having a top surface on which first connection members are disposed. The memory component also includes a second chip having a top surface on which second connection members are disposed and having a bottom surface to which a bottom surface of the first chip is attached. The memory component also includes a first insulation layer surrounding a portion of the first chip. The memory component also includes a second insulation layer surrounding a portion of the second chip. The memory component also includes a third insulation layer disposed between the first and second insulation layers, a plurality of first circuit patterns disposed on a bottom surface of the first insulation layer, and a plurality of second circuit patterns disposed on a top surface of the second insulation layer. The memory component also includes a fourth insulation layer disposed on the bottom surface of the first insulation layer to cover the plurality of first circuit patterns. The memory component also includes an external connection terminal penetrating the fourth insulation layer to contact any one of the plurality of first circuit patterns. The memory component also includes a fifth insulation layer disposed on the top surface of the second insulation to cover the plurality of second circuit patterns. The memory component also includes a metal layer disposed on a top surface of the fifth insulation layer. The memory component also includes lower vias penetrating the first insulation layer to electrically couple the first connection members to the first circuit patterns. The memory component also includes upper vias penetrating the second insulation layer to electrically couple the second connection members to the second circuit patterns. The memory component also includes first through electrodes penetrating the first to third insulation layers to electrically couple the first circuit patterns to the second circuit patterns. The memory component also includes second through electrodes penetrating the first to third insulation layers to electrically couple the first circuit patterns to the second circuit patterns. The memory component also includes connection vias penetrating the fifth insulation layer to electrically couple the metal layer to the second circuit patterns. Distances between the second through electrodes and the first or second chip are different.

### BRIEF DESCRIPTION OF THE DRAWINGS

FIG. 1 is a cross-sectional view illustrating an embedded package according to an embodiment;

FIG. 2 is a cross-sectional view illustrating an embedded package according to an embodiment;

FIG. 3 is a plan view illustrating a disposal relationship between a chip and through electrodes included in the embedded package of FIG. 2;

FIG. 4 is a cross-sectional view illustrating an embedded package according to still an embodiment;

FIG. 5 is a cross-sectional view illustrating an embedded package according to yet an embodiment;

FIG. 6 is a plan view illustrating a disposal relationship between chips and first through electrodes included in the embedded package of FIG. 5;

FIGS. 7 to 13 are cross-sectional views illustrating a method of fabricating an embedded package according to an embodiment;

FIGS. 14 to 21 are cross-sectional views and plan views illustrating a method of fabricating an embedded package according to an embodiment;

FIGS. 22 to 30 are cross-sectional views illustrating a method of fabricating an embedded package according to an embodiment;

FIGS. 31 to 40 are cross-sectional views and plan views illustrating a method of fabricating an embedded package according to an embodiment;

FIG. 41 is a block diagram illustrating an electronic system including at least one of embedded packages in accordance with various embodiments; and

FIG. 42 is a block diagram illustrating another electronic system including at least one of embedded packages in accordance with various embodiments.

### DETAILED DESCRIPTION

It will be understood that although the terms first, second, third etc. may be used to describe various elements, these elements should not be limited by these terms. These terms are only used to distinguish one element from another element. Thus, a first element in various embodiments could be termed a second element in other embodiments without departing from the teachings of the invention. Moreover, various embodiments are directed to embedded packages, methods of fabricating the same, electronic systems including the same, and memory cards including the same.

It will also be understood that when an element is referred to as being located “on,” “over,” “above,” “under,” “beneath” or “below” another element, it may directly contact the other element, or at least one intervening element may be present therebetween. Accordingly, the terms such as “on,” “over,” “above,” “under,” “beneath,” “below” and the like that are used are for the purpose of describing particular embodiments only and are not intended to limit the scope of the invention.

It will be further understood that when an element is referred to as being “electrically coupled” to another element, it can be directly electrically coupled or electrically coupled to the other element or intervening elements may be present. In contrast, when an element is referred to as being “directly electrically coupled” another element, there are no intervening elements present. Other words used to describe the relationship between elements or layers should be interpreted in a like fashion (e.g., “between” versus “directly between,” “adjacent” versus “directly adjacent,” “on” versus “directly on”). The term “chip” used herein may correspond to a memory chip such as a dynamic random access memory (DRAM) chip, a static random access memory (SRAM) chip, a flash memory chip, a magnetic random access memory (MRAM) chip, a resistive random access memory (ReRAM) chip, a ferroelectric random access memory (FeRAM) chip, or a phase change random access memory (PcRAM) chip. In the alternative, the term “chip” used herein may correspond to a logic chip, for example, a non-memory chip.

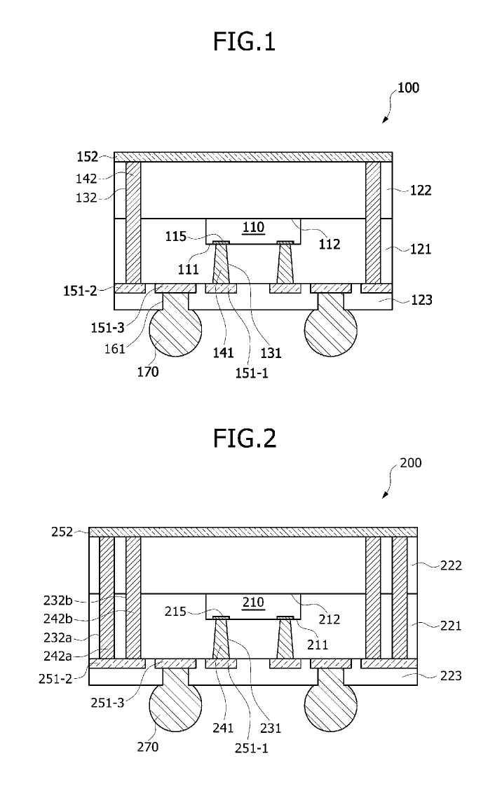

Referring to FIG. 1, a cross-sectional view illustrating an embedded package 100 according to an embodiment is described. Referring to FIG. 1, the embedded package 100 may include a first insulation layer 121, a second insulation layer 122 attached to the first insulation layer 121, and a chip 110 embedded in the first and second insulation layers 121 and 122. The chip 110 may have a top surface 111 and a bottom surface 112. Connection members 115 may be disposed on the top surface 111 of the chip 110. Although not shown in the figures, active regions of the chip 110 may be disposed to be adjacent to the top surface 111 on which the connection members 115 are disposed. In various embodiments, the connection members 115 may be metal pads. The second insulation layer 122 may be disposed on the first insulation layer 121. A top surface of the first insulation layer 121 may be attached to a bottom surface of the second insulation layer 122. The first and second insulation layers 121 and 122 may include the same material layer. In various embodiments, the first and second insulation layers 121 and 122 may include a resin material. For example, each of the first and second insulation layers 121 and 122 may include a resin-coated-copper (RCC) layer.

The chip 110 may be embedded in the first and second insulation layers 121 and 122 so that the top surface 111 of the chip 110 faces the first insulation layer 121. The chip 110 may be disposed between first and second insulation layers 121 and 122 so that the active regions and the connection members 115 of the chip 110 face down. Accordingly, the top surface 111 and sidewalls of the chip 110 may contact the first insulation layer 121. The bottom surface 112 of the chip 110 may be coplanar with a top surface of the first insulation layer 121. In such a case, a bottom surface of the second insulation layer 122 may contact the bottom surface 112 of the chip 110 and a top surface of the first insulation layer 121.

A metal layer 152 may be disposed on a top surface of the second insulation layer 122. The metal layer 152 may function as an upper electromagnetic interference (EMI) shielding layer of the embedded package 100. In addition, the metal layer 152 may also function as a heat radiator that emits the heat generated from the chip 110 into an outside region of the embedded package 100. In various embodiments, the metal layer 152 may be a copper layer formed by an electroplating process performed using a copper layer of an RCC layer of the second insulation layer 122 as a seed layer.

A plurality of circuit patterns 151-1, 151-2 and 151-3 may be disposed on a bottom surface of the first insulation layer 121. The circuit patterns 151-1 may be electrically coupled to the connection members 115 through lower vias 141. The lower vias 141 may be metal vias filling lower via holes 131 that penetrate the first insulation layer 121 to expose the connection members 115 of the chip 110. The lower vias 141 may provide signal paths between the chip 110 and external connection members 170. The circuit patterns 151-2 may be electrically coupled to the metal layer 152 via through electrodes 142. The through electrodes 142 may be metal electrodes filling through holes 132 that penetrate the first and second insulation layers 121 and 122 to expose the metal layer 152. A ground voltage may be applied to the metal layer 152 through the through electrodes 142. Accordingly, the through electrodes 142 may also function as side EMI shielding layers of the embedded package 100. The circuit patterns 151-3 may be electrically coupled to other connection members of the chip 110 or may be electrically coupled to the circuit patterns 151-1 and 151-2.

The plurality of circuit patterns 151-1, 151-2 and 151-3 may be formed by patterning a metal layer (i.e., a copper layer) grown by an electroplating process performed using a copper layer of an RCC layer of the first insulation layer 121 as a seed layer, like the metal layer 152. The lower vias 141 and the through electrodes 142 may include the same material as the plurality of circuit patterns 151-1, 151-2 and 151-3. In such a case, the metal layer for forming the circuit patterns 151-1, 151-2 and 151-3, the metal layer 152 on the second insulation layer 122, the lower vias 141, and the through electrodes 142 may be simultaneously formed by the same electroplating process.

A third insulation layer 123 may be disposed on a bottom surface of the first insulation layer 121 to cover the circuit patterns 151-1, 151-2 and 151-3. The third insulation layer 123 may have openings 161 that expose the circuit patterns 151-3. In various embodiments, the third insulation layer 123 may include a resin material. For example, the third insulation layer 123 may include an RCC layer. The external connection members 170, for example, solder balls may be disposed to be electrically coupled to the circuit patterns 151-3 exposed by the openings 161.

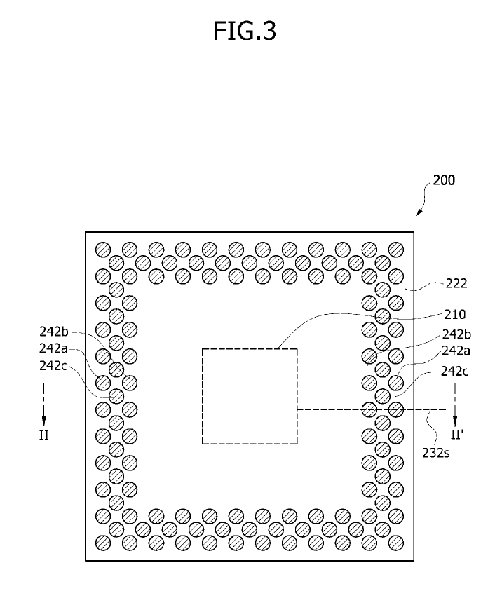

Referring to FIG. 2, a cross-sectional view illustrating an embedded package 200 according to an embodiment is described. Referring to FIG. 3, a plan view illustrating a disposal relationship between a chip and through electrodes included in the embedded package 200 of FIG. 2 is described. FIG. 2 is a cross-sectional view taken along a line II-II′ of FIG. 3. In FIG. 3, elements irrelevant to the disposal relationship between the chip and the through electrodes of the embedded package 200 are not illustrated to avoid complexity of the figure. Referring to FIGS. 2 and 3, the embedded package 200 may include a first insulation layer 221, a second insulation layer 222 attached to the first insulation layer 221, and a chip 210 embedded in the first and second insulation layers 221 and 222. The chip 210 may have a top surface 211 and a bottom surface 212. Connection members 215 may be disposed on the top surface 211 of the chip 210. Although not shown in the figures, active regions of the chip 210 may be disposed to be adjacent to the top surface 211 on which the connection members 215 are disposed. In various embodiments, the connection members 215 may be metal pads. The second insulation layer 222 may be disposed on the first insulation layer 221. A top surface of the first insulation layer 221 may be attached to a bottom surface of the second insulation layer 222. The first and second insulation layers 221 and 222 may include the same material layer. In various embodiments, the first and second insulation layers 221 and 222 may include a resin material. For example, each of the first and second insulation layers 221 and 222 may include a resin-coated-copper (RCC) layer.

The chip 210 may be embedded in the first and second insulation layers 221 and 222 so that the top surface 211 of the chip 210 faces the first insulation layer 221. The chip 210 may be disposed between first and second insulation layers 221 and 222 so that the active regions and the connection members 215 of the chip 210 face down. Accordingly, the top surface 211 and sidewalls of the chip 210 may contact the first insulation layer 221. The bottom surface 212 of the chip 210 may be coplanar with a top surface of the first insulation layer 221. In such a case, a bottom surface of the second insulation layer 222 may contact the bottom surface 212 of the chip 210 and a top surface of the first insulation layer 221.

A metal layer 252 may be disposed on a top surface of the second insulation layer 222. The metal layer 252 may function as an upper EMI shielding layer of the embedded package 200. In addition, the metal layer 252 may also function as a heat radiator that emits the heat generated from the chip 210 into an outside region of the embedded package 200. In various embodiments, the metal layer 252 may be a copper layer formed by an electroplating process performed using a copper layer of an RCC layer of the second insulation layer 222 as a seed layer.

A plurality of circuit patterns 251-1, 251-2 and 251-3 may be disposed on a bottom surface of the first insulation layer 221. The circuit patterns 251-1 may be electrically coupled to the connection members 215 through lower vias 241. The lower vias 241 may be metal vias filling lower via holes 231 that penetrate the first insulation layer 221 to expose the connection members 215 of the chip 210. The lower vias 241 may provide signal paths between the chip 210 and external connection members 270. The circuit patterns 251-2 may be electrically coupled to the metal layer 252 via through electrodes 242a, 242b and 242c. Each of the through electrodes 242a, 242b and 242c may be a metal electrode filling a through hole 232a, 232b or 232c that penetrates the first and second insulation layers 221 and 222 to expose the metal layer 252. A ground voltage may be applied to the metal layer 252 through the through electrodes 242a, 242b and 242c. Accordingly, the through electrodes 242a, 242b and 242c may also function as side EMI shielding layers of the embedded package 200. The circuit patterns 251-3 may be electrically coupled to other connection members of the chip 210 or may be electrically coupled to the circuit patterns 251-1 and 251-2.

As illustrated in FIG. 3 showing a planar layout of the through electrodes 242a, 242b and 242c, the through electrodes 242a, 242b and 242c may include outer through electrodes 242a, inner through electrodes 242b, and middle through electrodes 242c. The outer through electrodes 242a may be regularly arrayed along edges of the embedded package 200. Further, the inner through electrodes 242b may also be regularly arrayed along edges of the embedded package 200. Similarly, the middle through electrodes 242c may also be regularly arrayed along edges of the embedded package 200. More specifically, the outer through electrodes 242a may be regularly arrayed along edges of the embedded package 200 to be relatively far from the chip 210. Further, the inner through electrodes 242b may be regularly arrayed along edges of the embedded package 200 to be relatively close to the chip 210. The outer through electrodes 242a may be regularly arrayed on an outer closed loop line adjacent to sidewalls of the embedded package 200. In addition, the inner through electrodes 242b may be regularly arrayed on an inner closed loop line surrounded by the outer closed loop line. In various embodiments, each of the outer through electrodes 242a may be disposed to overlap with any one of the inner through electrodes 242b in a direction perpendicular to any one of sidewalls of the chip 210. For example, one of the outer through electrodes 242a and one of the inner through electrodes 242b may be disposed on a straight line 232s perpendicular to one of the sidewalls of the chip 210. The middle through electrodes 242c may be regularly arrayed on a middle closed loop line between the outer closed loop line and the inner closed loop line.

A distance between the chip 210 and the middle through electrodes 242c may be less than a distance between the chip 210 and the outer through electrodes 242a and may be greater than a distance between the chip 210 and the inner through electrodes 242b. Moreover, the outer through electrodes 242a and the middle through electrodes 242c may be arrayed in a zigzag fashion along the edges of the embedded package 200. Further, the inner through electrodes 242b and the middle through electrodes 242c may also be arrayed in a zigzag fashion along the edges of the embedded package 200. Accordingly, in each of corner regions of the embedded package 200 having a rectangular shape, one of the outer through electrodes 242a, one of the middle through electrodes 242c, and one of the inner through electrodes 242b may be sequentially disposed on a diagonal line that extends from a vertex of the embedded package 200 toward a central point of the embedded package 200 as illustrated in a plan view of FIG. 3. If the embedded package 200 includes the through electrodes 242a, 242b and 242c having the aforementioned configuration, at least one of the through electrodes 242a, 242b and 242c may be located on an arbitrary line that extends from any position of the chip 210 toward any position of the edges of the embedded package 200. Accordingly, the through electrodes 242a, 242b and 242c may maximize a side EMI shielding efficiency of the embedded package 200.

The plurality of circuit patterns 251-1, 251-2 and 251-3 may be formed by patterning a metal layer (i.e., a copper layer) grown by an electroplating process performed using a copper layer of an RCC layer of the first insulation layer 221 as a seed layer, like the metal layer 252. The lower vias 241 and the through electrodes 242a, 242b and 242c may include the same material as the plurality of circuit patterns 251-1, 251-2 and 251-3. In such a case, the metal layer for forming the circuit patterns 251-1, 251-2 and 251-3, the metal layer 252 on the second insulation layer 222, the lower vias 241, and the through electrodes 242a, 242b and 242c may be simultaneously formed by the same electroplating process.

A third insulation layer 223 may be disposed on a bottom surface of the first insulation layer 221 to cover the circuit patterns 251-1, 251-2 and 251-3. The third insulation layer 223 may have openings 261 that expose the circuit patterns 251-3. In various embodiments, the third insulation layer 223 may include a resin material. For example, the third insulation layer 223 may include an RCC layer. The external connection members 270, for example, solder balls may be disposed to be electrically coupled to the circuit patterns 251-3 exposed by the openings 261.

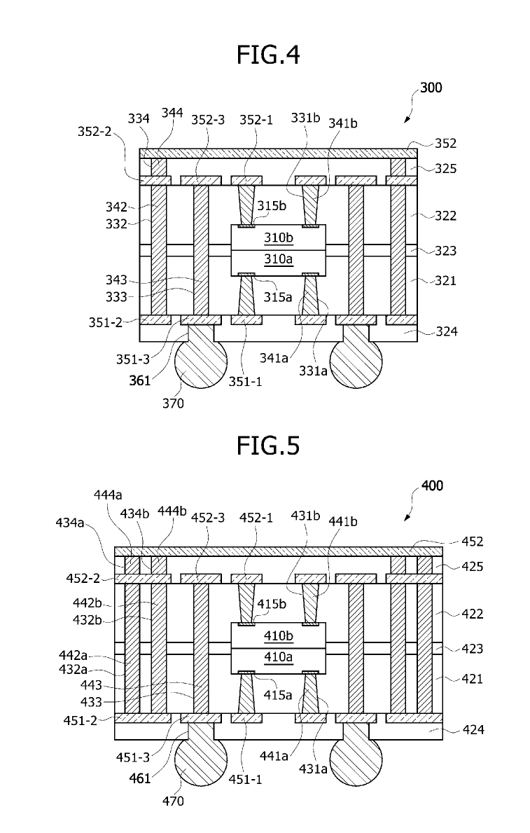

Referring to FIG. 4, a cross-sectional view illustrating an embedded package 300 according to an embodiment is illustrated. In FIG. 4, the embedded package 300 may include a first insulation layer 321, a second insulation layer 322, a third insulation layer 323, and first and second chips 310a and 310b embedded in the first, second and third insulation layers 321, 322 and 323. The first chip 310a may include first connection members 315a disposed on a top surface. The second chip 310b may include second connection members 315b disposed on a top surface thereof. Although not shown in the figures, active regions of the first chip 310a may be disposed to be adjacent to the top surface of the first chip 310a which the first connection members 315a are disposed on. In addition, active regions of the second chip 310b may be disposed to be adjacent to the top surface of the second chip 310b which the second connection members 315b are disposed on. In various embodiments, the first and second connection members 315a and 315b may be metal pads.

The third insulation layer 323 may be stacked on the first insulation layer 321. Further, the second insulation layer 322 may be stacked on the third insulation layer 323. A top surface of the first insulation layer 321 may be attached to a bottom surface of the third insulation layer 323. Moreover, a top surface of the third insulation layer 323 may be attached to a bottom surface of the second insulation layer 322. The first, second and third insulation layers 321, 322 and 323 may include the same material layer. In various embodiments, the first, second and third insulation layers 321, 322 and 323 may include a resin material. For example, each of the first, second and third insulation layers 321, 322 and 323 may include an RCC layer.

The first chip 310a may be embedded in the first, second and third insulation layers 321, 322 and 323 so that the top surface of the first chip 310a faces the first insulation layer 321. The first chip 310a may be disposed between the first and third insulation layers 321 and 323 so that the active regions and the first connection members 315a of the first chip 310a face down. Accordingly, the top surface of the first chip 310a and portions of sidewalls of the first chip 310a may contact the first insulation layer 321. Further, the remaining portions of the sidewalls of the first chip 310a may contact the third insulation layer 323. A bottom surface of the first chip 310a may contact a bottom surface of the second chip 310b. Thus, the second chip 310b may be disposed between the second and third insulation layers 322 and 323 so that the active regions and the second connection members 315b of the second chip 310b face up. Accordingly, the top surface of the second chip 310b and portions of sidewalls of the second chip 310b may contact the second insulation layer 322. Further, the remaining portions of the sidewalls of the second chip 310b may contact the third insulation layer 323.

A plurality of first circuit patterns 351-1, 351-2 and 351-3 may be disposed on a bottom surface of the first insulation layer 321. The first circuit patterns 351-1 may be electrically coupled to the first connection members 315a of the first chip 310a through lower vias 341a. The lower vias 341a may be metal vias filling lower via holes 331a that penetrate the first insulation layer 321 to expose the first connection members 315a of the first chip 310a. The lower vias 341a may provide signal paths between the first chip 310a and external connection members 370. The first circuit patterns 351-2 may be electrically coupled to first through electrodes 342. The first circuit patterns 351-3 may be electrically coupled to second through electrodes 343. In the alternative, the first circuit patterns 351-3 may be electrically coupled to other connection members of the first chip 310a or may be electrically coupled to the first circuit patterns 351-1 and 351-2.

A fourth insulation layer 324 may be disposed on a bottom surface of the first insulation layer 321 to cover the first circuit patterns 351-1, 351-2 and 351-3. The fourth insulation layer 324 may have openings 361 that expose the first circuit patterns 351-3. In various embodiments, the fourth insulation layer 324 may include a resin material. For example, the fourth insulation layer 324 may include an RCC layer. The external connection members 370, for example, solder balls may be disposed to be electrically coupled to the first circuit patterns 351-3 exposed by the openings 361.

A plurality of second circuit patterns 352-1, 352-2 and 352-3 may be disposed on a top surface of the second insulation layer 322. The second circuit patterns 352-1 may be electrically coupled to the second connection members 315b of the second chip 310b through upper vias 341b. The upper vias 341b may be metal vias filling upper via holes 331b that penetrate the second insulation layer 322 to expose the second connection members 315b of the second chip 310b. The upper vias 341b may provide signal paths between the second chip 310b and the external connection members 370. The second circuit patterns 352-2 may be electrically coupled to the first through electrodes 342. The second circuit patterns 352-3 may be electrically coupled to the second through electrodes 343. The second circuit patterns 352-3 may also be electrically coupled to other connection members of the second chip 310b or may be electrically coupled to the second circuit patterns 352-1 and 352-2.

The first through electrodes 342 may be metal electrodes filling first through holes 332 that penetrate the first, second and third insulation layers 321, 322 and 323. The first through electrodes 342 may electrically couple the first circuit patterns 351-2 to the second circuit patterns 352-2. The second through electrodes 343 may be metal electrodes filling second through holes 333 that penetrate the first, second and third insulation layers 321, 322 and 323. The second through electrodes 343 may electrically couple the first circuit patterns 351-3 to the second circuit patterns 352-3.

A fifth insulation layer 325 may be disposed on a top surface of the second insulation layer 322 to cover the second circuit patterns 352-1, 352-2 and 352-3. In various embodiments, the fifth insulation layer 325 may include a resin material. For example, the fifth insulation layer 325 may include an RCC layer. A metal layer 352 may be disposed on a top surface of the fifth insulation layer 325. The metal layer 352 may be electrically couple to the second circuit patterns 352-2 through connection vias 344. The connection vias 344 may be metal vias filling via holes 334 that penetrate the fifth insulation layer 325 to expose the second circuit patterns 352-2. A ground voltage may be applied to the metal layer 352 through the first through electrodes 342 and the connection vias 344. Accordingly, the first through electrodes 342 and the connection vias 344 may function as side EMI shielding layers of the embedded package 300. Further, the metal layer 352 may function as an upper EMI shielding layer of the embedded package 300. In addition, the metal layer 352 may also function as a heat radiator that emits the heat generated from the first and second chips 310a and 310b into an outside region of the embedded package 300. In various embodiments, the metal layer 352 may be a copper layer formed by an electroplating process performed using a copper layer of an RCC layer as a seed layer.

The first circuit patterns 351-1, 351-2 and 351-3 and the second circuit patterns 352-1, 352-2 and 352-3 may be formed by patterning a metal layer (i.e., a copper layer) grown by an electroplating process performed using copper layers of RCC layers of the first and second insulation layers 321 and 322 as seed layers, like the metal layer 352. The lower vias 341a, the upper vias 341b, the first through electrodes 342, the second through electrodes 343 and the connection vias 344 may include the same material as the first and second circuit patterns 351-1, 351-2, 351-3, 352-1, 352-2 and 352-3. In such a case, the metal layers for forming the first and second circuit patterns 351-1, 351-2, 351-3, 352-1, 352-2 and 352-3, the metal layer 352 on the fifth insulation layer 325, the lower vias 341a, the upper vias 341b, and the first and second through electrodes 342 and 343 may be simultaneously formed by the same electroplating process.

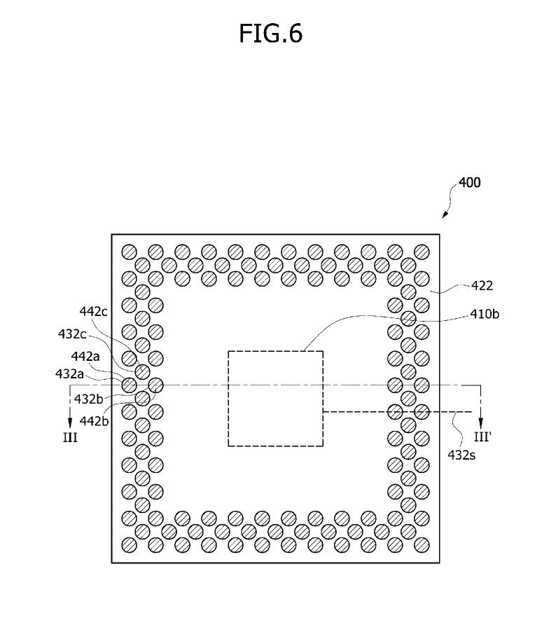

Referring to FIG. 5, a cross-sectional view illustrating an embedded package 400 according to an embodiment is described. Further, referring to FIG. 6, a plan view illustrating a disposal relationship between chips and first through electrodes included in the embedded package 400 of FIG. 5 is described. FIG. 5 is a cross-sectional view taken along a line III-III′ of FIG. 6. In FIG. 6, elements irrelevant to the disposal relationship between the chips and the first through electrodes of the embedded package 400 are not illustrated to avoid complexity of the figure. In FIGS. 5 and 6, the embedded package 400 may include a first insulation layer 421, a second insulation layer 422, a third insulation layer 423, and first and second chips 410a and 410b embedded in the first, second and third insulation layers 421, 422 and 423. The first chip 410a may include first connection members 415a disposed on a top surface. The second chip 410b may include second connection members 415b disposed on a top surface. Although not shown in the figures, active regions of the first chip 410a may be disposed to be adjacent to the top surface of the first chip 410a which the first connection members 415a are disposed on. Further, active regions of the second chip 410b may be disposed to be adjacent to the top surface of the second chip 410b which the second connection members 415b are disposed on. In various embodiments, the first and second connection members 415a and 415b may be metal pads.

The third insulation layer 423 may be stacked on the first insulation layer 421, and the second insulation layer 422 may be stacked on the third insulation layer 423. A top surface of the first insulation layer 421 may be attached to a bottom surface of the third insulation layer 423. Further, a top surface of the third insulation layer 423 may be attached to a bottom surface of the second insulation layer 422. The first, second and third insulation layers 421, 422 and 423 may include the same material layer. In various embodiments, the first, second and third insulation layers 421, 422 and 423 may include a resin material. For example, each of the first, second and third insulation layers 421, 422 and 423 may include an RCC layer.

The first chip 410a may be embedded in the first, second and third insulation layers 421, 422 and 423 so that the top surface of the first chip 410a faces the first insulation layer 421. The first chip 410a may be disposed between the first and third insulation layers 421 and 423 so that the active regions and the first connection members 415a of the first chip 410a face down. Accordingly, the top surface of the first chip 410a and portions of sidewalls of the first chip 410a may contact the first insulation layer 421. Further, the remaining portions of the sidewalls of the first chip 410a may contact the third insulation layer 423. A bottom surface of the first chip 410a may contact a bottom surface of the second chip 410b. Thus, the second chip 410b may be disposed between the second and third insulation layers 422 and 423 so that the active regions and the second connection members 415b of the second chip 410b face up. Accordingly, the top surface of the second chip 410b and portions of sidewalls of the second chip 410b may contact the second insulation layer 422. Moreover, the remaining portions of the sidewalls of the second chip 410b may contact the third insulation layer 423.

A plurality of first circuit patterns 451-1, 451-2 and 451-3 may be disposed on a bottom surface of the first insulation layer 421. The first circuit patterns 451-1 may be electrically coupled to the first connection members 415a of the first chip 410a through lower vias 441a. The lower vias 441a may be metal vias filling lower via holes 431a that penetrate the first insulation layer 421 to expose the first connection members 415a of the first chip 410a. The lower vias 441a may provide signal paths between the first chip 410a and external connection members 470. The first circuit patterns 451-2 may be electrically coupled to first through electrodes 442a, 442b and 442c. The first circuit patterns 451-3 may be electrically coupled to second through electrodes 443. Alternatively, the first circuit patterns 451-3 may be electrically coupled to other connection members of the first chip 410a or may be electrically coupled to the first circuit patterns 451-1 and 451-2.

A fourth insulation layer 424 may be disposed on a bottom surface of the first insulation layer 421 to cover the first circuit patterns 451-1, 451-2 and 451-3. The fourth insulation layer 424 may have openings 461 that expose the first circuit patterns 451-3. In various embodiments, the fourth insulation layer 424 may include a resin material. For example, the fourth insulation layer 424 may include an RCC layer. The external connection members 470, for example, solder balls may be disposed to be electrically coupled to the first circuit patterns 451-3 exposed by the openings 461.

A plurality of second circuit patterns 452-1, 452-2 and 452-3 may be disposed on a top surface of the second insulation layer 422. The second circuit patterns 452-1 may be electrically coupled to the second connection members 415b of the second chip 410b through upper vias 441b. The upper vias 441b may be metal vias filling upper via holes 431b that penetrate the second insulation layer 422 to expose the second connection members 415b of the second chip 410b. The upper vias 441b may provide signal paths between the second chip 410b and the external connection members 470. The second circuit patterns 452-2 may be electrically coupled to the first through electrodes 442a, 442b and 442c. The second circuit patterns 452-3 may be electrically coupled to the second through electrodes 443. The second circuit patterns 452-3 may also be electrically coupled to other connection members of the second chip 410b or may be electrically coupled to the second circuit patterns 452-1 and 452-2.

Each of the first through electrodes 442a may be a metal electrode filling a first through hole 432a that penetrates the first, second and third insulation layers 421, 422 and 423. In addition, each of the first through electrodes 442b may be a metal electrode filling a first through hole 432b that penetrates the first, second and third insulation layers 421, 422 and 423. Moreover, each of the first through electrodes 442c may be a metal electrode filling a first through hole 432c that penetrates the first, second and third insulation layers 421, 422 and 423. The first through electrodes 442a, 442b and 442c may electrically couple the first circuit patterns 451-2 to the second circuit patterns 452-2. Each of the second through electrodes 443 may be a metal electrode filling a second through hole 433 that penetrates the first, second and third insulation layers 421, 422 and 423. The second through electrodes 443 may electrically couple the first circuit patterns 451-3 to the second circuit patterns 452-3.

Referring to FIG. 6, a planar layout of the first through electrodes 442a, 442b and 442c, the first through electrodes 442a, 442b and 442c may include first outer through electrodes 442a, first inner through electrodes 442b, and first middle through electrodes 442c. The first outer through electrodes 442a may be regularly arrayed along edges of the embedded package 400. Further, the first inner through electrodes 442b may also be regularly arrayed along edges of the embedded package 400. Similarly, the first middle through electrodes 442c may also be regularly arrayed along edges of the embedded package 400. More specifically, the first outer through electrodes 442a may be regularly arrayed along edges of the embedded package 400 to be relatively far from the first and second chips 410a and 410b. In addition, the first inner through electrodes 442b may be regularly arrayed along edges of the embedded package 400 to be relatively close to the first and second chips 410a and 410b. The first outer through electrodes 442a may be regularly arrayed on an outer closed loop line adjacent to sidewalls of the embedded package 400. Further, the first inner through electrodes 442b may be regularly arrayed on an inner closed loop line surrounded by the outer closed loop line. In various embodiments, each of the outer through electrodes 442a may be disposed to overlap with any one of the first inner through electrodes 442b in a direction perpendicular to any one of sidewalls of the first chip 410a (or the second chip 410b). For example, one of the first outer through electrodes 442a and one of the first inner through electrodes 442b may be disposed on a straight line 432s perpendicular to one of the sidewalls of the first or second chip 410a or 410b. The first middle through electrodes 442c may be regularly arrayed on a middle closed loop line between the outer closed loop line and the inner closed loop line.

A distance between the first or second chip 410a or 410b and the first middle through electrodes 442c may be less than a distance between the first or second chip 410a or 410b and the first outer through electrodes 442a and may be greater than a distance between the first or second chip 410a or 410b and the first inner through electrodes 242b. Moreover, the first outer through electrodes 442a and the first middle through electrodes 442c may be arrayed in a zigzag fashion along the edges of the embedded package 400. Further, the first inner through electrodes 442b and the first middle through electrodes 442c may also be arrayed in a zigzag fashion along the edges of the embedded package 400. Accordingly, in each of corner regions of the embedded package 400 having a rectangular shape, one of the first outer through electrodes 442a, one of the first middle through electrodes 442c, and one of the first inner through electrodes 442b may be sequentially disposed on a diagonal line that extends from a vertex of the embedded package 400 toward a central point of the embedded package 400, as illustrated in a plan view of FIG. 6. If the embedded package 400 includes the first through electrodes 442a, 442b and 442c having the aforementioned configuration, at least one of the first through electrodes 442a, 442b and 442c may be located on an arbitrary line that extends from any position of the first or second chip 410a or 410b toward any position of the edges of the embedded package 400. Accordingly, the first through electrodes 442a, 442b and 442c may maximize a side EMI shielding efficiency of the embedded package 400.

A fifth insulation layer 425 may be disposed on a top surface of the second insulation layer 422 to cover the second circuit patterns 452-1, 452-2 and 452-3. In various embodiments, the fifth insulation layer 425 may include a resin material. For example, the fifth insulation layer 425 may include an RCC layer. A metal layer 452 may be disposed on a top surface of the fifth insulation layer 425. The metal layer 452 may be electrically coupled to the second circuit patterns 452-2 through connection vias 444a and 444b. The metal layer 452 may function as an upper EMI shielding layer of the embedded package 400. In addition, the metal layer 452 may also function as a heat radiator that emits the heat generated from the first and second chips 410a and 410b into an outside region of the embedded package 400. In various embodiments, the metal layer 452 may be a copper layer formed by an electroplating process performed using a copper layer of an RCC layer as a seed layer.

Each of the connection vias 444a may be a metal via filling a via hole 434a that penetrates the fifth insulation layer 425 to expose the second circuit pattern 352-2. In addition, each of the connection vias 444b may also be a metal via filling a via hole 434b that penetrates the fifth insulation layer 425 to expose the second circuit pattern 352-2. In various embodiments, the connection vias 444a may be disposed to respectively overlap with the first through electrodes 442a in a plan view. Further, the connection vias 444b may be disposed to respectively overlap with the first through electrodes 442b in a plan view. Although not shown in FIG. 5, additional connection vias may be disposed to respectively overlap with the first middle through electrodes 442c in a plan view. The number of the connection vias 444a and 444b may be different according to the embodiments. In various embodiments, only the connection vias 444a or 444b may be disposed in the fifth insulation layer 425.

The first circuit patterns 451-1, 451-2 and 451-3 and the second circuit patterns 452-1, 452-2 and 452-3 may be formed by patterning a metal layer (i.e., a copper layer) grown by an electroplating process performed using copper layers of RCC layers of the first and second insulation layers 421 and 422 as seed layers, like the metal layer 452. The lower vias 441a, the upper vias 441b, the first through electrodes 442a, 442b and 442c, the second through electrodes 443 and the connection vias 444a and 444b may include the same material as the first and second circuit patterns 451-1, 451-2, 451-3, 452-1, 452-2 and 452-3. In such a case, the metal layers for forming the first and second circuit patterns 451-1, 451-2, 451-3, 452-1, 452-2 and 452-3, the metal layer 452 on the fifth insulation layer 425, the lower vias 441a, the upper vias 441b, the first through electrodes 442a, 442b and 442c, and the second through electrodes 443 may be simultaneously formed by the same electroplating process.

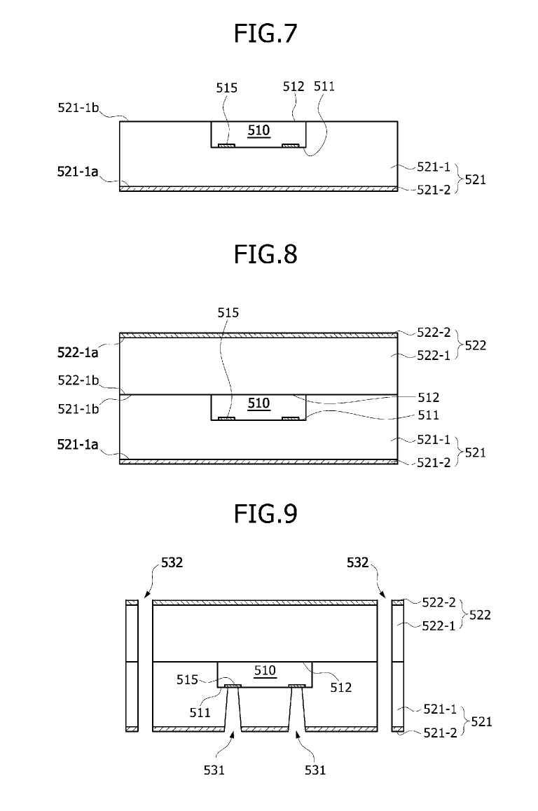

Referring to FIGS. 7 to 13, cross-sectional views illustrating a method of fabricating an embedded package according to an embodiment are described. In FIG. 7, a chip 510 may be embedded in a first insulation layer 521. The chip 510 may have a top surface 511 and a bottom surface 512. Connection members 515 may be formed on the top surface 511 of the chip 510. In various embodiments, the connection members 515 may be metal pads. The first insulation layer 521 may be an RCC layer. The first insulation layer 521 may include an insulation body 521-1 formed of a resin material and a copper layer 521-2 formed on a surface of the insulation body 521-1. The insulation body 521-1 may have a first surface 521-1a and a second surface 521-1b opposite to the first surface 521-1a. The copper layer 521-2 may be coated on the first surface 521-1a of the insulation body 521-1.

To embed the chip 510 in the first insulation layer 521, the chip 510 may be attached to a temporary substrate. The chip 510 may be attached to a surface of the temporary substrate. Subsequently, the first insulation layer 521 may be located over the top surface 511 of the chip 510 attached to the temporary substrate. In such a case, the first insulation layer 521 may be disposed so that the chip 510 is under the second surface 521-1b of the insulation body 521-1 opposite to the copper layer 521-2. The chip 510 may then be embedded in the first insulation layer 521 using a vacuum lamination technique. After the chip 510 is embedded in the first insulation layer 521, the temporary substrate may be detached from the chip 510. Accordingly, the chip 510 may be embedded in the first insulation layer 521 so that the top surface 511 and sidewalls of the chip 510 contact the first insulation layer 521 and the bottom surface 512 of the chip 510 may be exposed at the second surface 521-1b of the insulation body 521-1. The exposed bottom surface 512 of the chip 510 may be substantially coplanar with the second surface 521-1b of the insulation body 521-1.

In FIG. 8, a second insulation layer 522 may be attached to the bottom surface 512 of the chip 510 and the second surface 521-1b of the insulation body 521-1. The second insulation layer 522 may be an RCC layer. The second insulation layer 522 may include an insulation body 522-1 formed of a resin material and a copper layer 522-2 formed on a surface of the insulation body 522-1. The insulation body 522-1 may have a first surface 522-1a and a second surface 522-1b that is opposite to the first surface 522-1a. The copper layer 522-2 may be coated on the first surface 522-1a of the insulation body 522-1. The second surface 522-1b of the insulation body 522-1 may be attached to the bottom surface 512 of the chip 510 and the second surface 521-1b of the insulation body 521-1. The chip 510 may be embedded in the first and second insulation layers 521 and 522.

Referring to FIG. 9, lower via holes 531 and through holes 532 may be formed in the first and second insulation layers 521 and 522. The lower via holes 531 may be formed to penetrate the copper layer 521-2 and the insulation body 521-1 and to expose the connection members 515. The through holes 532 may be formed to penetrate edges of the first and second insulation layers 521 and 522. The lower via holes 531 and through holes 532 may be formed using a laser drilling process. In various embodiments, ultraviolet (UV) laser may be used to form holes penetrating the copper layers 521-2 and 522-2. Further, carbon dioxide (CO₂) laser may be used to form holes penetrating the insulation bodies 521-1 and 522-1. If the CO₂ laser is used to form holes penetrating the insulation bodies 521-1 and 522-1, about one thousand and five hundreds holes may be formed without generation of damage to the connection members 515 for one second. The through holes 532 may be formed along the edges of the first and second insulation layers 521 and 522 to be spaced apart from sidewalls of the chip 510.

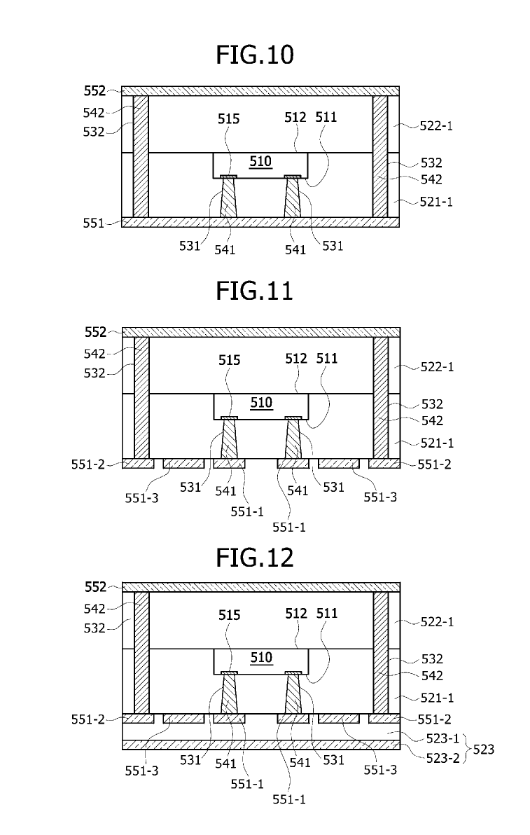

Referring to FIG. 10, a metal layer may be formed to fill the lower via holes 531 and the through holes 532. As a result, lower vias 541 may be formed in the lower via holes 531. Further, through electrodes 542 may be formed in the through holes 532. In addition, a first metal layer 551 and a second metal layer 552 may be formed on the copper layer 521-2 and the copper layer 522-2, respectively. In various embodiments, the lower vias 541, the through electrodes 542, the first metal layer 551, and the second metal layer 552 may be formed using an electroplating process. In such a case, the copper layers 521-2 and 522-2 may be used as seed layers. The lower vias 541 may electrically couple the connection members 515 of the chip 510 to the first metal layer 551. Further, the through electrodes 542 may electrically couple the first metal layer 551 to the second metal layer 552.

Before the electroplating process for forming the lower vias 541 and the through electrodes 542 is performed, a process for improving an adhesive strength between the metal layer filling the lower via holes 531 and the through holes 532 and the insulation bodies 521-1 and 522-1 may be performed. To perform the process for improving an adhesive strength between the metal layer filling the lower via holes 531 and the through holes 532 and the insulation bodies 521-1 and 522-1, sidewalls of the lower via holes 531 and the through holes 532 may be activated. This activation process may be performed by depositing a conductive palladium colloid material on the sidewalls of the lower via holes 531 and the through holes 532. Moreover, before the electroplating process for forming the lower vias 541 and the through electrodes 542 is performed, a cleaning process such as a de-smear treatment process may be additionally performed so that the lower vias 541 are formed without defects. The de-smear treatment process may be performed to remove organic residues that remain on the connection members 515 exposed by the lower via holes 531.

In FIG. 11, the first metal layer (551 of FIG. 10) may be patterned to form a plurality of circuit patterns 551-1, 551-2 and 551-3. The circuit patterns 551-1 may be formed to contact the lower vias 541. Further, the circuit patterns 551-2 may be formed to contact the through electrodes 542. The circuit patterns 551-3 may be formed to be electrically coupled to other connection members of the chip 510 or to be electrically coupled to the circuit patterns 551-1 and 551-2. In various embodiments, in order to pattern the first metal layer (551 of FIG. 10), a dry film resist layer may be formed on the first metal layer (551 of FIG. 10) to a thickness of about 5 micrometers to about 150 micrometers and predetermined regions of the dry film resist layer may be selectively removed using UV rays to form a dry film resist pattern exposing portions of the first metal layer (551 of FIG. 10). Subsequently, the exposed portions of the first metal layer (551 of FIG. 10) may be removed by an acidic spray etching process to form the plurality of circuit patterns 551-1, 551-2 and 551-3, and the dry film resist pattern may then be removed.

In FIG. 12, a third insulation layer 523 may be formed on the insulation body 521-1 of the first insulation layer 521 to cover the circuit patterns 551-1, 551-2 and 551-3. The third insulation layer 523 may be formed of an RCC layer. The third insulation layer 523 may be formed to include an insulation body 523-1 comprised of a resin material and a copper layer 523-2 coated on a surface of the insulation body 523-1 opposite to the first insulation layer 521. Accordingly, the insulation body 523-1 of the third insulation layer 523 may be attached to the insulation body 521-1 of the first insulation layer 521 exposed between the circuit patterns 551-1, 551-2 and 551-3.

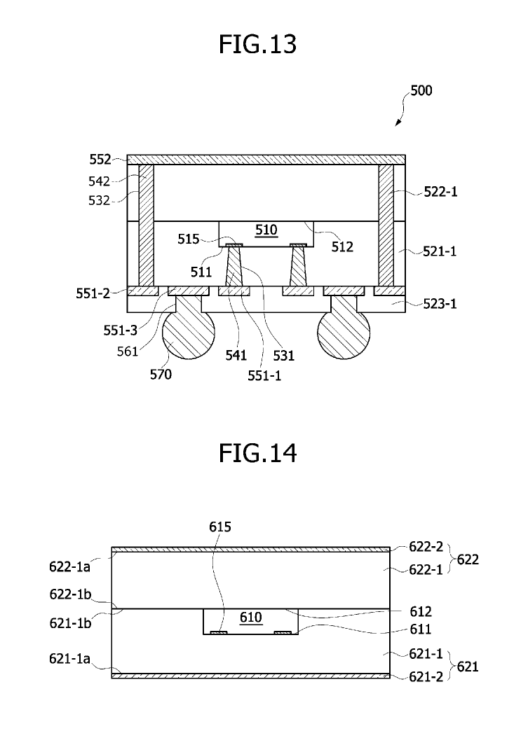

In FIG. 13, the third insulation layer 523 may be patterned to form openings 561 that expose the circuit patterns 551-3. While the openings 561 are formed, the copper layer 523-2 of the third insulation layer 523 may be removed. Subsequently, external connection members 570 such as solder balls may be formed on the third insulation layer 523 to compete an embedded package 500. The solder balls 570 may be formed to contact the circuit patterns 551-3 through the openings 561. Contact structures between the solder balls 570 and the circuit patterns 551-3 may be realized to be different according to various embodiments.

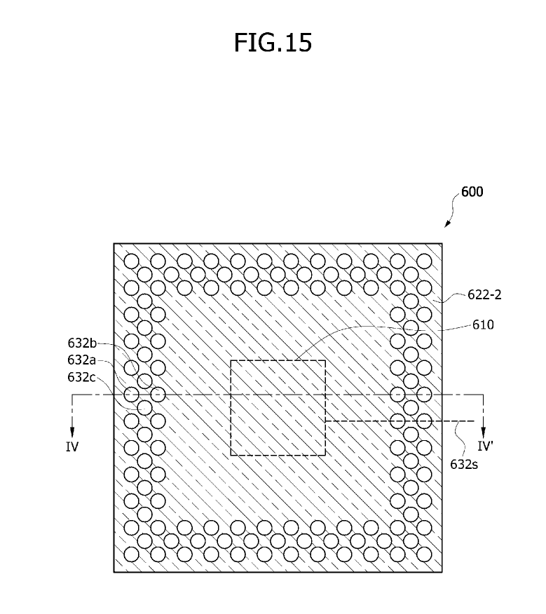

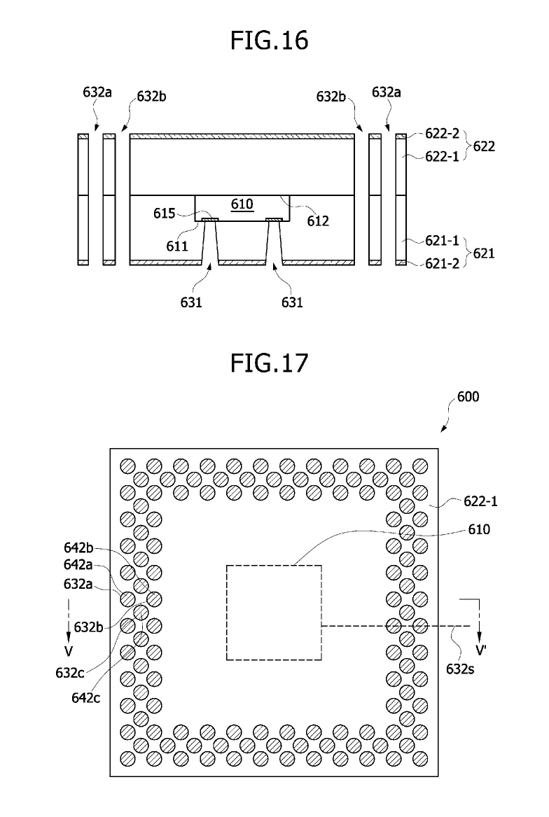

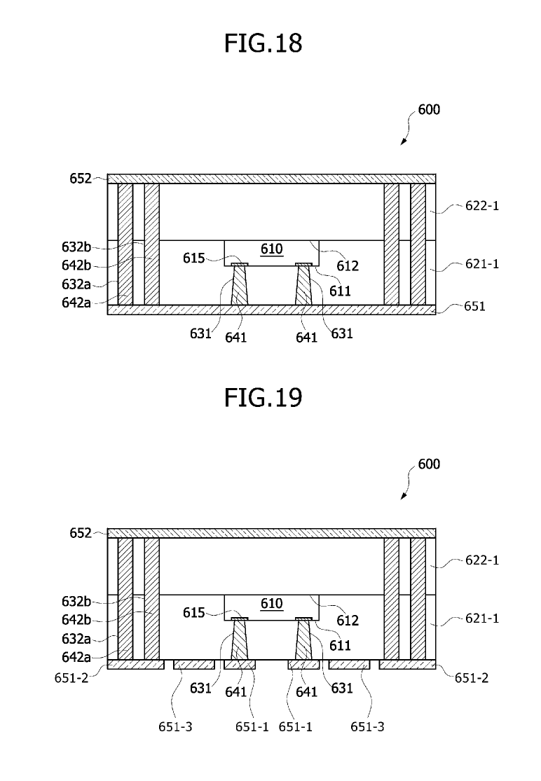

Referring to FIGS. 14 to 21, cross-sectional views and plan views illustrating a method of fabricating an embedded package according to an embodiment are illustrated. FIGS. 16 and 18 are cross-sectional views taken along a line IV-IV′ of FIG. 15 and a line V-V′ of FIG. 17, respectively. In FIG. 17, a metal layer 652 of FIG. 18 is not illustrated to avoid complexity of the figure. In FIG. 14, a chip 610 may be embedded in a first insulation layer 621 and a second insulation layer 622. The chip 610 may be embedded in the first and second insulation layers 621 and 622 using the same manner as described with reference to with FIGS. 7 and 8. The chip 610 may have a top surface 611 on which connection members 615 are disposed and a bottom surface 612 which is opposite to the top surface 611. Each of the first and second insulation layers 621 and 622 may be an RCC layer. The first insulation layer 621 may include an insulation body 621-1 formed of a resin material and a copper layer 621-2 formed on a surface of the insulation body 621-1. The insulation body 621-1 may have a first surface 621-1a and a second surface 621-1b that is opposite to the first surface 621-1a. Further, the copper layer 621-2 may be coated on the first surface 621-1a of the insulation body 621-1. The second insulation layer 622 may also include an insulation body 622-1 formed of a resin material and a copper layer 622-2 formed on a surface of the insulation body 622-1. The insulation body 622-1 may have a first surface 622-1a and a second surface 622-1b that is opposite to the first surface 622-1a. In addition, the copper layer 622-2 may be coated on the first surface 622-1a of the insulation body 622-1.

In FIGS. 15 and 16, lower via holes 631 and through holes 632a, 632b and 632c may be formed in the first and second insulation layers 621 and 622. The lower via holes 631 may be formed to penetrate the copper layer 621-2 and the insulation body 621-1 and to expose the connection members 615. The through holes 632a, 632b and 632c may be formed to penetrate edges of the first and second insulation layers 621 and 622. The lower via holes 631 and the through holes 632a, 632b and 632c may be formed using a laser drilling process. In various embodiments, ultraviolet (UV) laser may be used to form holes penetrating the copper layers 621-2 and 622-2. Further, carbon dioxide (CO₂) laser may be used to form holes penetrating the insulation bodies 621-1 and 622-1. If the CO₂ laser is used to form holes penetrating the insulation bodies 621-1 and 622-1, about one thousand and five hundreds holes may be formed without generation of damage to the connection members 615 for one second. The through holes 632a, 632b and 632c may be formed along the edges of the first and second insulation layers 621 and 622 to be spaced apart from sidewalls of the chip 610.

In FIG. 15, the through holes 632a, 632b and 632c may include outer through holes 632a, inner through holes 632b, and middle through holes 632c. The outer through holes 632a may be regularly arrayed along edges of the first and second insulation layers 621 and 622. Further, the inner through holes 632b may also be regularly arrayed along edges of the first and second insulation layers 621 and 622. Similarly, the middle through holes 632c may also be regularly arrayed along edges of the first and second insulation layers 621 and 622. More specifically, the outer through holes 632a may be regularly arrayed along edges of the first and second insulation layers 621 and 622 to be relatively far from the chip 610. In addition, the inner through holes 632b may be regularly arrayed along edges of the first and second insulation layers 621 and 622 to be relatively close to the chip 610. The outer through holes 632a may be regularly arrayed on an outer closed loop line which is adjacent to sidewalls of the first and second insulation layers 621 and 622. Further, the inner through holes 632b may be regularly arrayed on an inner closed loop line surrounded by the outer closed loop line. In various embodiments, each of the outer through holes 632a may be disposed to overlap with any one of the inner through holes 632b in a direction perpendicular to any one of sidewalls of the chip 610. For example, one of the outer through holes 632a and one of the inner through holes 632b may be disposed on a straight line 632s perpendicular to one of the sidewalls of the chip 610. The middle through holes 632c may be regularly arrayed on a middle closed loop line between the outer closed loop line and the inner closed loop line.

A distance between the chip 610 and the middle through holes 632c may be less than a distance between the chip 610 and the outer through holes 632a and may be greater than a distance between the chip 610 and the inner through holes 632b. Moreover, the outer through holes 632a and the middle through holes 632c may be arrayed in a zigzag fashion along the edges of the first and second insulation layers 621 and 622. Further, the inner through holes 632b and the middle through holes 632c may also be arrayed in a zigzag fashion along the edges of the first and second insulation layers 621 and 622. Accordingly, in each of corner regions of the first and second insulation layers 621 and 622 having a rectangular shape, one of the outer through holes 632a, one of the middle through holes 632c, and one of the inner through holes 632b may be sequentially disposed on a diagonal line that extends from a vertex of the first insulation layer 621 (or the second insulation layer 622) toward a central point of the chip 610, as illustrated in a plan view of FIG. 15. If the through holes 632a, 632b and 632c are disposed to have the aforementioned configuration, at least one of the through holes 632a, 632b and 632c may be located on an arbitrary line that extends from any position of the chip 610 toward any position of the edges of the first insulation layer 621 (or the second insulation layer 622).

In FIGS. 17 and 18, a metal layer may be formed to fill the lower via holes 631 and the through holes 632a, 632b and 632c. As a result, lower vias 641 may be respectively formed in the lower via holes 631. In addition, outer through electrodes 642a may be respectively formed in the outer through holes 632a. Further, inner through electrodes 642b may be respectively formed in the inner through holes 632b. Similarly, middle through electrodes 642c may be respectively formed in the middle through holes 632c. Moreover, a first metal layer 651 and a second metal layer 652 may be formed on the copper layer 621-2 and the copper layer 622-2, respectively. In various embodiments, the lower vias 641, the through electrodes 642a, 642b and 642c, the first metal layer 651, and the second metal layer 652 may be formed using an electroplating process. In such a case, the copper layers 621-2 and 622-2 may be used as seed layers. The lower vias 641 may electrically couple the connection members 615 of the chip 610 to the first metal layer 651. Further, the through electrodes 642a, 642b and 642c may electrically couple the first metal layer 651 to the second metal layer 652.

Before the electroplating process for forming the lower vias 641 and the through electrodes 642a, 642b and 642c is performed, a process for improving an adhesive strength between the metal layer filling the lower via holes 631 and the through holes 632a, 632b and 632c and the insulation bodies 621-1 and 622-1 may be performed. To perform the process for improving an adhesive strength between the metal layer filling the lower via holes 631 and the through holes 632a, 632b and 632c and the insulation bodies 621-1 and 622-1, sidewalls of the lower via holes 631 and the through holes 632a, 632b and 632c may be activated. This activation process may be performed by depositing a conductive palladium colloid material on the sidewalls of the lower via holes 631 and the through holes 632a, 632b and 632c. Moreover, before the electroplating process for forming the lower vias 641 and the through electrodes 642a, 642b and 642c is performed, a cleaning process such as a de-smear treatment process may be additionally performed so that the lower vias 641 are formed without defects. The de-smear treatment process may be performed to remove organic residues that remain on the connection members 615 exposed by the lower via holes 631.

In FIG. 19, the first metal layer (651 of FIG. 18) may be patterned to form a plurality of circuit patterns 651-1, 651-2 and 651-3. The circuit patterns 651-1 may be formed to contact the lower vias 641. In addition, the circuit patterns 651-2 may be formed to contact the through electrodes 642a and 642b. Although not shown in FIG. 19, the circuit patterns 651-2 may also be formed to contact the middle through electrodes 642c in addition to the outer and inner through electrodes 642a and 642b. The circuit patterns 651-3 may be formed to be electrically coupled to other connection members of the chip 610 or to be electrically coupled to the circuit patterns 651-1 and 651-2. In various embodiments, in order to pattern the first metal layer (651 of FIG. 18), a dry film resist layer may be formed on the first metal layer (651 of FIG. 18) to a thickness of about 5 micrometers to about 150 micrometers and predetermined regions of the dry film resist layer may be selectively removed using UV rays to form a dry film resist pattern exposing portions of the first metal layer (651 of FIG. 18). Subsequently, the exposed portions of the first metal layer (651 of FIG. 18) may be removed by an acidic spray etching process to form the plurality of circuit patterns 651-1, 651-2 and 651-3, and the dry film resist pattern may then be removed.

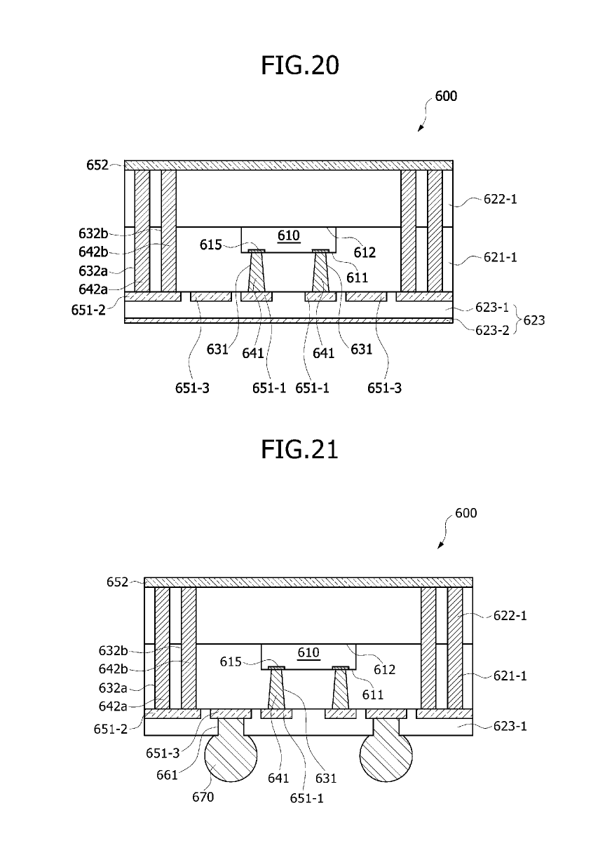

In FIG. 20, a third insulation layer 623 may be formed on the insulation body 621-1 of the first insulation layer 621 to cover the circuit patterns 651-1, 651-2 and 651-3. The third insulation layer 623 may be formed of an RCC layer. The third insulation layer 623 may be formed to include an insulation body 623-1 comprised of a resin material and a copper layer 623-2 coated on a surface of the insulation body 623-1 opposite to the first insulation layer 621. Accordingly, the insulation body 623-1 of the third insulation layer 623 may be attached to the insulation body 621-1 of the first insulation layer 621 exposed between the circuit patterns 651-1, 651-2 and 651-3.

In FIG. 21, the third insulation layer 623 may be patterned to form openings 661 that expose the circuit patterns 651-3. While the openings 661 are formed, the copper layer 623-2 of the third insulation layer 623 may be removed. Subsequently, external connection members 670 such as solder balls may be formed on the third insulation layer 623 to compete an embedded package 600. The solder balls 670 may be formed to contact the circuit patterns 651-3 through the openings 661. Contact structures between the solder balls 670 and the circuit patterns 651-3 may be realized to be different according to various embodiments.

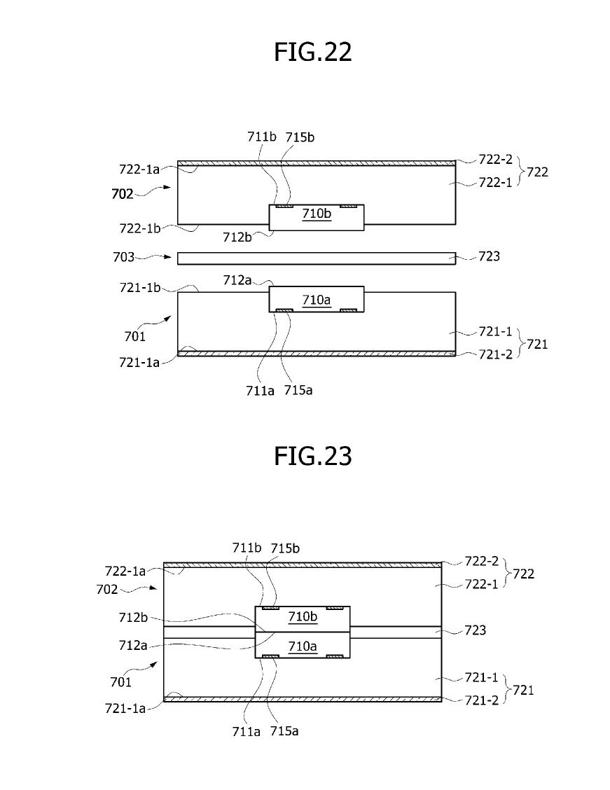

Referring to FIGS. 22 to 30, cross-sectional views illustrating a method of fabricating an embedded package according to an embodiment are described. In FIG. 22, a first structure 701, a second structure 702 and a third structure 703 may be provided. The first structure 701 may be provided to include a first insulation layer 721 and a first chip 710a embedded in the first insulation layer 721. Further, the second structure 702 may be provided to include a second insulation layer 722 and a second chip 710b embedded in the second insulation layer 722. The third structure 703 may be provided to include a third insulation layer 723. The first chip 710a may have a top surface 711a and a bottom surface 712a. First connection members 715a may be disposed on the top surface 711a of the first chip 710a. In various embodiments, the first connection members 715a may be metal pads. The second chip 710b may have a top surface 711b and a bottom surface 712b. Second connection members 715b may be disposed on the top surface 711b of the second chip 710b. In various embodiments, the second connection members 715b may be metal pads.

The first insulation layer 721 may be an RCC layer. The first insulation layer 721 may include an insulation body 721-1 formed of a resin material and a copper layer 721-2 formed on a surface of the insulation body 721-1. The insulation body 721-1 may have a first surface 721-1a and a second surface 721-1b that is opposite to the first surface 721-1a. The copper layer 721-2 may be coated on the first surface 721-1a of the insulation body 721-1. The second insulation layer 722 may be the same material as the first insulation layer 721. The second insulation layer 722 may be an RCC layer. In such a case, the second insulation layer 722 may include an insulation body 722-1 formed of a resin material and a copper layer 722-2 formed on a surface of the insulation body 722-1. The insulation body 722-1 may have a first surface 722-1a and a second surface 722-1b that is opposite to the first surface 722-1a. The copper layer 722-2 may be coated on the first surface 722-1a of the insulation body 722-1. The third insulation layer 723 may be the same material as the insulation bodies 721-1 and 722-1. For example, the third insulation layer 723 may be formed of a resin material without any copper layer.

In the first structure 701, the first chip 710a may be partially embedded in the insulation body 721-1 so that an entire portion of the top surface 711a of the first chip 710a and upper portions of sidewalls of the first chip 710a are buried in the insulation body 721-1. Further, an entire portion of the bottom surface 712a of the first chip 710a and lower portions of the sidewalls of the first chip 710a are exposed. In the second structure 702, the second chip 710b may be partially embedded in the insulation body 722-1 so that an entire portion of the top surface 711b of the second chip 710b and upper portions of sidewalls of the second chip 710b are buried in the insulation body 722-1. In addition, an entire portion of the bottom surface 712b of the second chip 710b and lower portions of the sidewalls of the second chip 710b are exposed.

The third structure 703 may be disposed over the first structure 701. Further, the second structure 702 may be disposed over the third structure 703. More specifically, the third structure 703 may be disposed over the second surface 721-1b of the insulation body 721-1 and the bottom surface 712a of the first chip 710a. In addition, the second structure 702 may be disposed over the third structure 703 so that the second surface 722-1b of the insulation body 722-1 and the bottom surface 712b of the second chip 710b face the third structure 703. In such a case, the first structure 701, the third structure 703 and the second structure 702 may be aligned with each other to vertically overlap with each other.

Referring to FIG. 23, a vacuum lamination technique may be applied to the first structure 701, the third structure 703 and the second structure 702 vertically aligned with each other, thereby embedding the first and second chips 710a and 710b in the first, second and third insulation layers 721, 722 and 723. In various embodiments, the bottom surface 712a of the first chip 710a may directly contact the bottom surface 712b of the second chip 710b. In the alternative, after the vacuum lamination technique is applied, the bottom surface 712a of the first chip 710a may be spaced apart from the bottom surface 712b of the second chip 710b. In addition, the third insulation layer 723 may be disposed between the bottom surface 712a of the first chip 710a and the bottom surface 712b of the second chip 710b. The first chip 710a may be embedded in the first and third insulation layers 721 and 723 so that active regions and the first connection members 715a of the first chip 710a face down. In contrast, the second chip 710b may be embedded in the second and third insulation layers 722 and 723 so that active regions and the second connection members 715b of the second chip 710b face up.

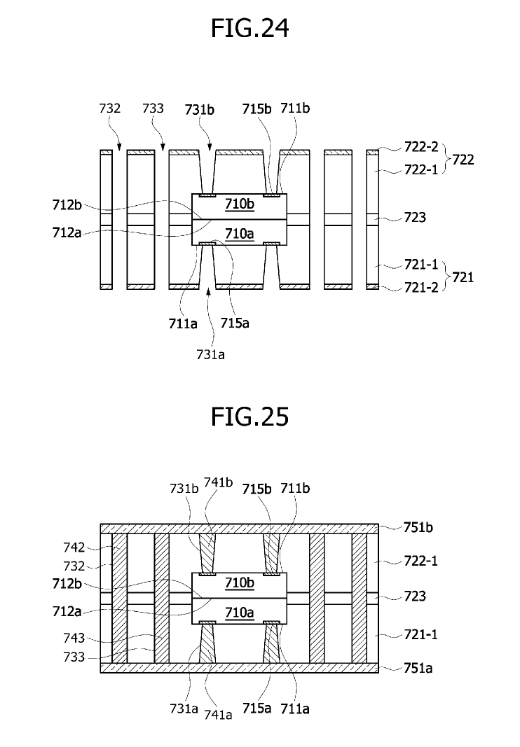

Referring to FIG. 24, the first insulation layer 721 may be patterned to form lower via holes 731a exposing the first connection members 715a of the first chip 710a. The lower via holes 731a may penetrate the copper layer 721-2 and the insulation body 721-1 to expose the first connection members 715a of the first chip 710a. The second insulation layer 722 may be patterned to form upper via holes 731b exposing the second connection members 715b of the second chip 710b. The upper via holes 731b may penetrate the copper layer 722-2 and the insulation body 722-1 to expose the second connection members 715b of the second chip 710b. In addition, the first, second and third insulation layers 721, 722 and 723 may be patterned to form first through holes 732 and second through holes 733 that penetrate the first, second and third insulation layers 721, 722 and 723. The lower via holes 731a, the upper via holes 731b, the first through holes 732 and the second through holes 733 may be formed using a laser drilling process. In various embodiments, ultraviolet (UV) laser may be used to form holes penetrating the copper layers 721-2 and 722-2. In addition, carbon dioxide (CO₂) laser may be used to form holes penetrating the insulation bodies 721-1 and 722-1. If the CO₂ laser is used to form holes penetrating the insulation bodies 721-1 and 722-1, about one thousand and five hundreds holes may be formed without generation of damage to the first and second connection members 715a and 715b for one second. The first through holes 732 may be formed along the edges of the first, second and third insulation layers 721, 722 and 723 to be spaced apart from sidewalls of the first and second chips 710a and 710b. The second through holes 733 may be formed between the first through holes 732 and the first chip 710a (or the second chip 710b).

Referring to FIG. 25, a metal layer may be formed to fill the lower via holes 731a, the upper via holes 731b, the first through holes 732 and the second through holes 733. As a result, lower vias 741a may be formed in the lower via holes 731a. In addition, upper vias 741b may be formed in the upper via holes 731b. In addition, first through electrodes 742 may be formed in the first through holes 732, and second through electrodes 743 may be formed in the second through holes 733. Moreover, a first metal layer 751a and a second metal layer 751b may be formed on the copper layer 721-2 and the copper layer 722-2, respectively. In various embodiments, the lower vias 741a, the upper vias 741b, the first through electrodes 742, the second through electrodes 743, the first metal layer 751a, and the second metal layer 751b may be formed using an electroplating process. In such a case, the copper layers 721-2 and 722-2 may be used as seed layers. The lower vias 741a may electrically couple the first connection members 715a of the first chip 710a to the first metal layer 751a. Further, the upper vias 741b may electrically couple the second connection members 715b of the second chip 710b to the second metal layer 751b. The first and second through electrodes 742 and 743 may electrically couple the first metal layer 751a to the second metal layer 751b.

Before the electroplating process for forming the lower vias 741a, the upper vias 741b, and the first and second through electrodes 742 and 743 is performed, a process for improving an adhesive strength between the metal layer filling the lower and upper via holes 731a and 731b and the first and second through holes 732 and 733 and the insulation bodies 721-1 and 722-1 may be performed. To perform the process for improving an adhesive strength between the metal layer filling the lower and upper via holes 731a and 731b and the first and second through holes 732 and 733 and the insulation bodies 721-1 and 722-1, sidewalls of the lower and upper via holes 731a and 731b and the first and second through holes 732 and 733 may be activated. This activation process may be performed by depositing a conductive palladium colloid material on the sidewalls of the lower and upper via holes 731a and 731b and the first and second through holes 732 and 733. Moreover, before the electroplating process for forming the lower and upper vias 741a and 741b and the first and second through electrodes 742 and 743 is performed, a cleaning process such as a de-smear treatment process may be additionally performed so that the lower and upper vias 741a and 741b are formed without defects. The de-smear treatment process may be performed to remove organic residues that remain on the first and second connection members 715a and 715b exposed by the lower and upper via holes 731a and 731b.

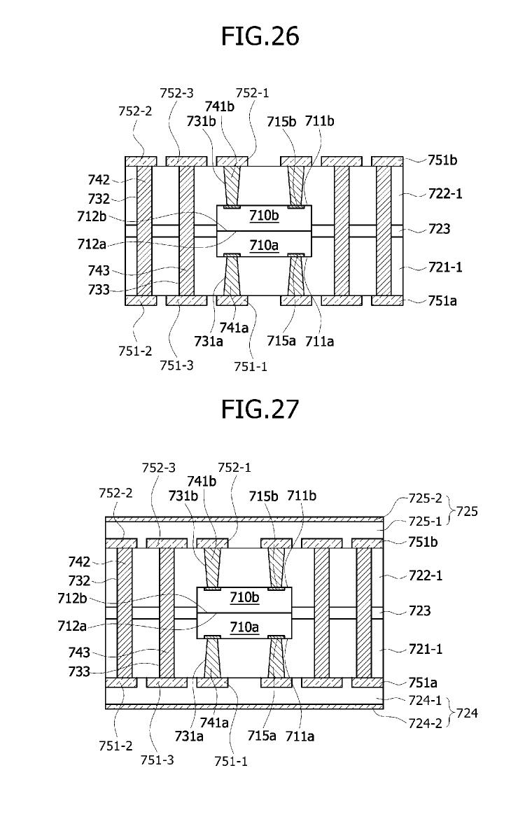

Referring to FIG. 26, the first metal layer (751a of FIG. 25) and the second metal layer (751b of FIG. 25) may be patterned to form a plurality of first circuit patterns 751-1, 751-2 and 751-3 and a plurality of second circuit patterns 752-1, 752-2 and 752-3. The first circuit patterns 751-1 may be formed to contact the lower vias 741a. In addition, the first circuit patterns 751-2 may be formed to contact the first through electrodes 742. The first circuit patterns 751-3 may be formed to contact the second through electrodes 743. The first circuit patterns 751-3 may be formed to be electrically coupled to other first connection members of the first chip 710a or to be electrically coupled to the other first circuit patterns 751-1 and 751-2. The second circuit patterns 752-1 may be formed to contact the upper vias 741b. Further, the second circuit patterns 752-2 may be formed to contact the first through electrodes 742. The second circuit patterns 752-3 may be formed to contact the second through electrodes 743. The first circuit patterns 752-3 may be formed to be electrically coupled to other second connection members of the second chip 710b or to be electrically coupled to the other second circuit patterns 752-1 and 752-2.

In various embodiments, in order to pattern the first metal layer (751a of FIG. 25) and the second metal layer (751b of FIG. 25), a dry film resist layer may be formed on the first and second metal layers (751a and 751b of FIG. 25) to a thickness of about 5 micrometers to about 150 micrometers and predetermined regions of the dry film resist layer may be selectively removed using UV rays to form a dry film resist pattern exposing portions of the first and second metal layers (751a and 751b of FIG. 25). Subsequently, the exposed portions of the first metal layer (751a and 751b of FIG. 25) may be removed by an acidic spray etching process to form the plurality of first and second circuit patterns 751-1, 751-2, 751-3, 752-1, 752-2 and 752-3. Further, the dry film resist pattern may then be removed.

Referring to FIG. 27, a fourth insulation layer 724 may be formed on the insulation body 721-1 of the first insulation layer 721 to cover the first circuit patterns 751-1, 751-2 and 751-3. The fourth insulation layer 724 may be formed of an RCC layer. The fourth insulation layer 724 may be formed to include an insulation body 724-1 comprised of a resin material and a copper layer 724-2 coated on a surface of the insulation body 724-1 opposite to the first insulation layer 721. Accordingly, the insulation body 724-1 of the fourth insulation layer 724 may be attached to the insulation body 721-1 of the first insulation layer 721 exposed between the first circuit patterns 751-1, 751-2 and 751-3.

Similarly, a fifth insulation layer 725 may be formed on the insulation body 722-1 of the second insulation layer 722 to cover the second circuit patterns 752-1, 752-2 and 752-3. The fifth insulation layer 725 may be formed of an RCC layer. The fifth insulation layer 725 may be formed to include an insulation body 725-1 comprised of a resin material and a copper layer 725-2 coated on a surface of the insulation body 725-1 opposite to the second insulation layer 722. Accordingly, the insulation body 725-1 of the fifth insulation layer 725 may be attached to the insulation body 722-1 of the second insulation layer 722 exposed between the second circuit patterns 752-1, 752-2 and 752-3.

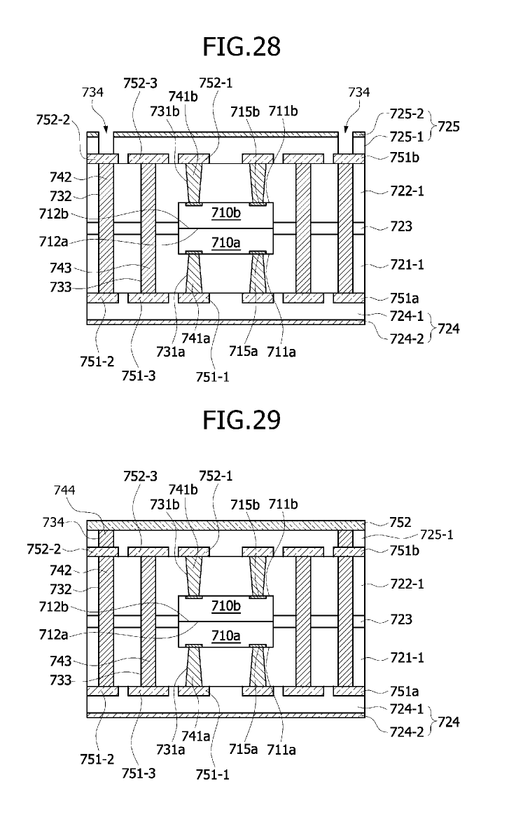

Referring to FIG. 28, the fifth insulation layer 725 may be patterned to form via holes 734 exposing the second circuit patterns 752-2. In various embodiments, the via holes 734 may be formed to vertically overlap with the first through electrodes 742. In the alternative, the via holes 734 may be formed not to vertically overlap with the first through electrodes 742. The via holes 734 may be formed using a laser process.

Referring to FIG. 29, a metal layer may be formed to fill the via holes 734. Accordingly, connection vias 744 may be formed in the via holes 734. In addition, a metal layer 752 may be formed on a top surface of the fifth insulation layer 725. In various embodiments, the connection vias 744 and the metal layer 752 may be formed using an electroplating process. In such a case, the second circuit patterns 752-2 and the copper layer 725-2 of the fifth insulation layer 725 may be used as seed layers. The connection vias 744 may electrically couple the second circuit patterns 752-2 to the metal layer 752.

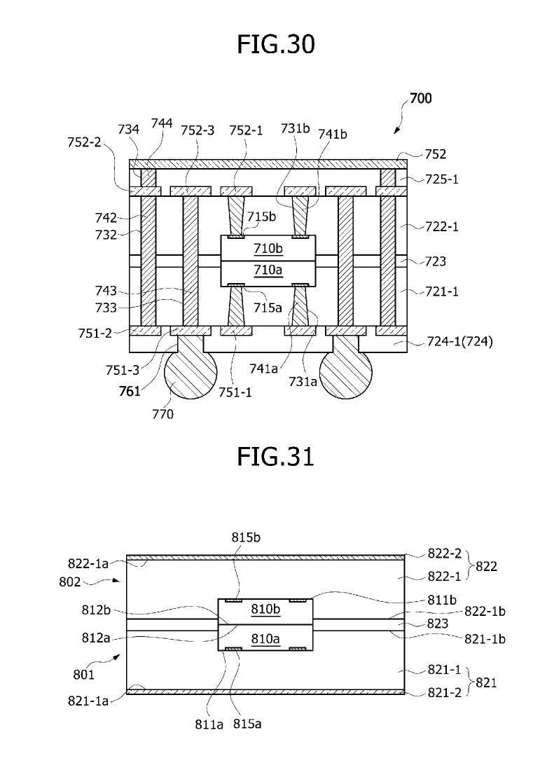

Referring to FIG. 30, the fourth insulation layer 724 may be patterned to form openings 761 that expose the first circuit patterns 751-3. While the openings 761 are formed, the copper layer 724-2 of the fourth insulation layer 724 may be removed. In various embodiments, the copper layer 724-2 may be removed to expose the insulation body 724-1 before forming the openings 761. The insulation body 724-1 may then be patterned to form the openings 761. In other various embodiments, the copper layer 724-2 may be patterned to expose portions of the insulation body 724-1. The exposed portions of the insulation body 724-1 may then be removed to form the openings 761. After the openings 761 are formed, the patterned copper layer 724-2 may be removed.

Subsequently, external connection members 770 such as solder balls may be formed on the fourth insulation layer 724 to compete an embedded package 700. The solder balls 770 may be formed to contact the first circuit patterns 751-3 through the openings 761. Contact structures between the solder balls 770 and the first circuit patterns 751-3 may be realized to be different according to various embodiments.

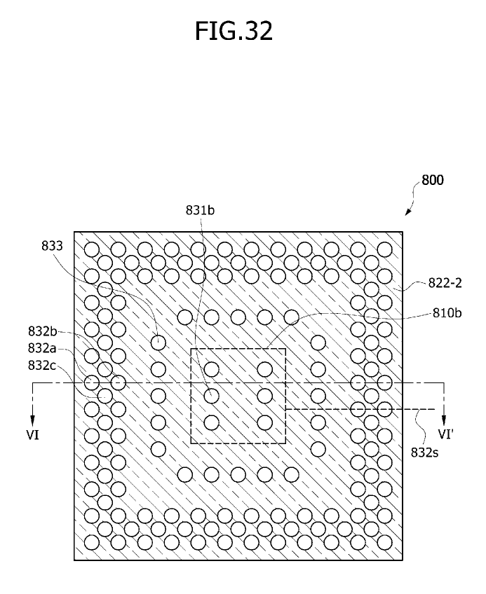

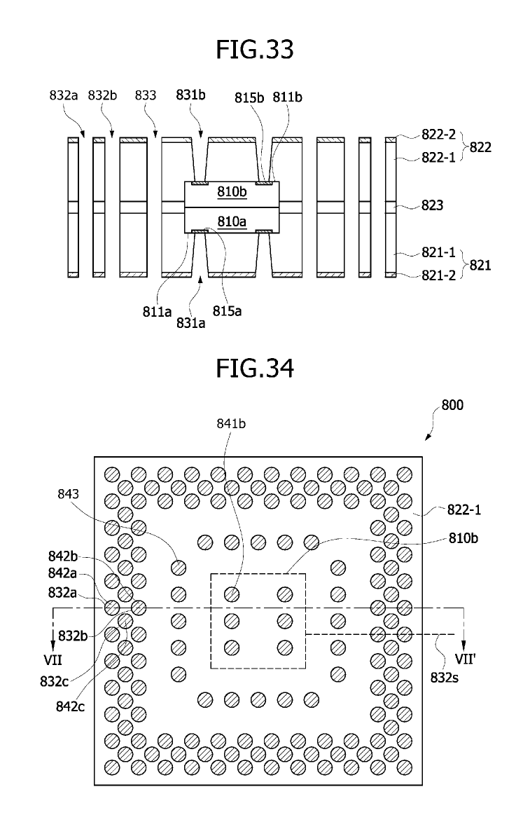

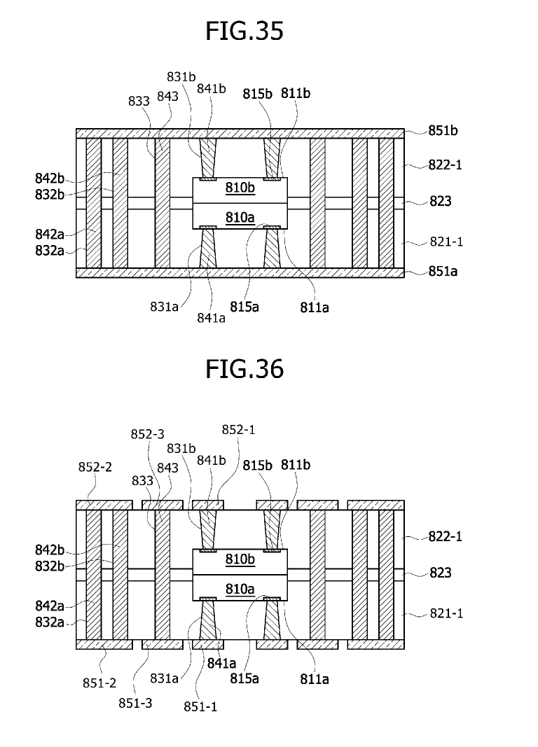

Referring to FIGS. 31 to 40, cross-sectional views and plan views illustrating a method of fabricating an embedded package according to an embodiment are illustrated. FIGS. 33 and 35 are cross-sectional views taken along a line VI-VI′ of FIG. 32 and a line VII-VII′ of FIG. 34, respectively. In FIG. 31, the first structure 801 may be provided to include a first insulation layer 821 and a first chip 810a. The second structure 802 may be provided to include a second insulation layer 822 and a second chip 810b. The first and second chips 810a and 810b may be embedded in the first, second and third insulation layers 821, 822 and 823 using the same manner as described with reference to with FIGS. 22 and 23. Accordingly, the first chip 810a may be disposed under the second chip 810b. The first chip 810a may have a top surface 811a on which first connection members 815a are disposed and a bottom surface 812a which is opposite to the top surface 811a. The second chip 810b may have a top surface 811b on which second connection members 815b are disposed and a bottom surface 812b which is opposite to the top surface 811b. In various embodiments, the bottom surface 812a of the first chip 810a may directly contact the bottom surface 812b of the second chip 810b. In the alternative, the bottom surface 812a of the first chip 810a may be spaced apart from the bottom surface 812b of the second chip 810b. Further, the third insulation layer 823 may be disposed between the bottom surface 812a of the first chip 810a and the bottom surface 812b of the second chip 810b. The first chip 810a may be embedded in the first and third insulation layers 821 and 823 so that active regions and the first connection members 815a of the first chip 810a face down. In contrast, the second chip 810b may be embedded in the second and third insulation layers 822 and 823 so that active regions and the second connection members 815b of the second chip 810b face up.

Each of the first and second insulation layers 821 and 822 may be an RCC layer. The first insulation layer 821 may include an insulation body 821-1 formed of a resin material and a copper layer 821-2 formed on a surface of the insulation body 821-1. Further, the second insulation layer 822 may include an insulation body 822-1 formed of a resin material and a copper layer 822-2 formed on a surface of the insulation body 822-1. The insulation body 821-1 may have a first surface 821-1a and a second surface 821-1b that is opposite to the first surface 821-1a. In addition, the copper layer 821-2 may be coated on the first surface 821-1a of the insulation body 821-1 opposite to the third insulation layer 823. The insulation body 822-1 may have a first surface 822-1a and a second surface 822-1b that is opposite to the first surface 822-1a. Further, the copper layer 822-2 may be coated on the first surface 822-1a of the insulation body 822-1 opposite to the third insulation layer 823. The third insulation layer 823 may be the same material layer as the insulation bodies 821-1 and 822-1. For example, the third insulation layer 823 may be comprised of only a resin material layer without any copper layer. The third insulation layer 823 may be disposed between the second surface 822-1b of the insulation body 822-1 and the second surface 821-1b of the insulation body 821-1. Accordingly, the copper layer 822-2 may be exposed on the insulation body 822-1. In addition, the copper layer 821-2 may be exposed under the insulation body 821-1.

In FIGS. 32 and 33, lower via holes 831a, upper via holes 831b, first through holes 832a, 832b and 832c, and second through holes 833 may be formed in the first, second and third insulation layers 821, 822 and 823. The lower via holes 831a may be formed to penetrate the copper layer 821-2 and the insulation body 821-1 and to expose the first connection members 815a. The upper via holes 831b may be formed to penetrate the copper layer 822-2 and the insulation body 822-1 and to expose the second connection members 815b. The first through holes 832a, 832b and 832c may be formed to penetrate edges of the first, second and third insulation layers 821, 822 and 823. The second through holes 833 may be formed to penetrate the first, second and third insulation layers 821, 822 and 823 between the first through holes 832a, 832b and 832c and the first chip 810a (or the second chip 810b). The lower via holes 831a, the upper via holes 831b, the first through holes 832a, 832b and 832c. Further, the second through holes 833 may be formed using a laser drilling process. In various embodiments, ultraviolet (UV) laser may be used to form holes penetrating the copper layers 821-2 and 822-2. In addition, carbon dioxide (CO₂) laser may be used to form holes penetrating the insulation bodies 821-1 and 822-1 and the third insulation layer 823. If the CO₂ laser is used to form holes penetrating the insulation bodies 821-1 and 822-1 and the third insulation layer 823, about one thousand and five hundreds holes may be formed without generation of damage to the first and second connection members 815a and 815b for one second.

In FIG. 32, the first through holes 832a, 832b and 832c may include first outer through holes 832a, first inner through holes 832b, and first middle through holes 832c. The first outer through holes 832a may be regularly arrayed along edges of the first, second and third insulation layers 821, 822 and 823. Further, the first inner through holes 832b may also be regularly arrayed along edges of the first, second and third insulation layers 821, 822 and 823. Similarly, the first middle through holes 832c may also be regularly arrayed along edges of the first, second and third insulation layers 821, 822 and 823. More specifically, the first outer through holes 832a may be regularly arrayed along edges of the first to third insulation layers 821, 822 and 823 to be relatively far from the first and second chips 810a and 810b. In addition, the first inner through holes 832b may be regularly arrayed along edges of the first to third insulation layers 821, 822 and 823 to be relatively close to the first and second chips 810a and 810b. The first outer through holes 832a may be regularly arrayed on an outer closed loop line which is adjacent to sidewalls of the first to third insulation layers 821, 822 and 823. In addition, the first inner through holes 832b may be regularly arrayed on an inner closed loop line surrounded by the outer closed loop line. In various embodiments, each of the first outer through holes 832a may be disposed to overlap with any one of the first inner through holes 832b in a direction perpendicular to any one of sidewalls of the first or second chip 810a or 810b. For example, one of the first outer through holes 832a and one of the first inner through holes 832b may be disposed on a straight line 832s perpendicular to one of the sidewalls of the first or second chip 810a or 810b. The first middle through holes 832c may be regularly arrayed on a middle closed loop line between the outer closed loop line and the inner closed loop line.

A distance between the first chip 810a (or the second chip 810b) and the first middle through holes 832c may be less than a distance between the first chip 810a (or the second chip 810b) and the first outer through holes 832a and may be greater than a distance between the first chip 810a (or the second chip 810b) and the first inner through holes 832b. Moreover, the first outer through holes 832a and the first middle through holes 832c may be arrayed in a zigzag fashion along the edges of the first to third insulation layers 821, 822 and 823. In addition, the first inner through holes 832b and the first middle through holes 832c may also be arrayed in a zigzag fashion along the edges of the first to third insulation layers 821, 822 and 823. Accordingly, in each of corner regions of the first to third insulation layers 821, 822 and 823 having a rectangular shape, one of the first outer through holes 832a, one of the first middle through holes 832c, and one of the first inner through holes 832b may be sequentially disposed on a diagonal line that extends from a vertex of one of the first to third insulation layers 821, 822 and 823 toward a central point of the first or second chip 810a or 810b, as illustrated in a plan view of FIG. 32. If the first through holes 832a, 832b and 832c are disposed to have the aforementioned configuration, at least one of the first through holes 832a, 832b and 832c may be located on an arbitrary line that extends from any position of the first or second chip 810a or 810b toward any position of the edges of the first, second or third insulation layer 821, 822 or 823.

In FIGS. 34 and 35, a metal layer may be formed to fill the lower via holes 831a, upper via holes 831b, the first through holes 832a, 832b and 832c, and the second through holes 833. As a result, lower vias 841a may be respectively formed in the lower via holes 831a. Further, upper vias 841b may be respectively formed in the upper via holes 831b. In addition, first outer through electrodes 842a may be respectively formed in the first outer through holes 832a. In addition, first inner through electrodes 842b may be respectively formed in the first inner through holes 832b. Similarly, first middle through electrodes 842c may be respectively formed in the first middle through holes 832c. Moreover, second through electrodes 843 may be respectively formed in the second through holes 833. Furthermore, a first metal layer 851a and a second metal layer 851b may be formed on the copper layer (821-2 of FIG. 33) and the copper layer (822-2 of FIG. 33), respectively. In various embodiments, the lower vias 841a, the upper vias 841b, the first through electrodes 842a, 842b and 842c, the second through electrodes 843, the first metal layer 851a, and the second metal layer 851b may be formed using an electroplating process. In such a case, the copper layers 821-2 and 822-2 may be used as seed layers. The lower vias 841a may electrically couple the first connection members 815a of the first chip 810a to the first metal layer 851a. Further, the upper vias 841b may electrically couple the second connection members 815b of the second chip 810b to the second metal layer 851b. In addition, the first and second through electrodes 842a, 842b, 842c and 843 may electrically couple the first metal layer 851a to the second metal layer 851b.

Before the electroplating process for forming the lower vias 841a, the upper vias 841b, the first through electrodes 842a, 842b and 842c, and the second through electrodes 843 is performed, a process for improving an adhesive strength between the metal layer filling the lower and upper via holes 831a and 831b and the first and second through holes 832a, 832b, 832c and 833 and the insulation bodies 821-1 and 822-1 may be performed. To perform the process for improving an adhesive strength between the metal layer filling the lower and upper via holes 831a and 831b and the first and second through holes 832a, 832b, 832c and 833 and the insulation bodies 821-1 and 822-1, sidewalls of the lower and upper via holes 831a and 831b and the first and second through holes 832a, 832b, 832c and 833 may be activated. This activation process may be performed by depositing a conductive palladium colloid material on the sidewalls of the lower and upper via holes 831a and 831b and the first and second through holes 832a, 832b, 832c and 833. Moreover, before the electroplating process for forming the lower and upper vias 841a and 841b and the first and second through electrodes 842a, 842b, 842c and 843 is performed, a cleaning process such as a de-smear treatment process may be additionally performed so that the lower and upper vias 841a and 841b are formed without defects. The de-smear treatment process may be performed to remove organic residues that remain on the first and second connection members 815a and 815b exposed by the lower and upper via holes 831a and 831b.

In FIG. 36, the first metal layer (851a of FIG. 35) and the second metal layer (851b of FIG. 35) may be patterned to form a plurality of first circuit patterns 851-1, 851-2 and 851-3 and a plurality of second circuit patterns 852-1, 852-2 and 852-3. The first circuit patterns 851-1 may be formed to contact the lower vias 841a. In addition, the first circuit patterns 851-2 may be formed to contact the first through electrodes 842a and 842b. Although not shown in the cross-sectional view of FIG. 36, the first circuit patterns 851-2 may also be formed to contact the first middle through electrodes 842c. The first circuit patterns 851-3 may be formed to contact the second through electrodes 843. The first circuit patterns 851-3 may be formed to be electrically coupled to other first connection members of the first chip 810a or to be electrically coupled to the other first circuit patterns 851-1 and 851-2. The second circuit patterns 852-1 may be formed to contact the upper vias 841b. In addition, the second circuit patterns 852-2 may be formed to contact the first through electrodes 842a and 842b. Although not shown in the cross-sectional view of FIG. 36, the second circuit patterns 852-2 may also be formed to contact the first middle through electrodes 842c. The second circuit patterns 852-3 may be formed to contact the second through electrodes 843. The first circuit patterns 852-3 may be formed to be electrically coupled to other second connection members of the second chip 810b or to be electrically coupled to the other second circuit patterns 852-1 and 852-2.

In various embodiments, in order to pattern the first metal layer (851a of FIG. 35) and the second metal layer (851b of FIG. 35), a dry film resist layer may be formed on the first and second metal layers (851a and 851b of FIG. 35) to a thickness of about 5 micrometers to about 150 micrometers and predetermined regions of the dry film resist layer may be selectively removed using UV rays to form a dry film resist pattern exposing portions of the first and second metal layers (851a and 851b of FIG. 35). Subsequently, the exposed portions of the first metal layer (851a and 851b of FIG. 35) may be removed by an acidic spray etching process to form the plurality of first and second circuit patterns 851-1, 851-2, 851-3, 852-1, 852-2 and 852-3. Furthermore, the dry film resist pattern may then be removed.

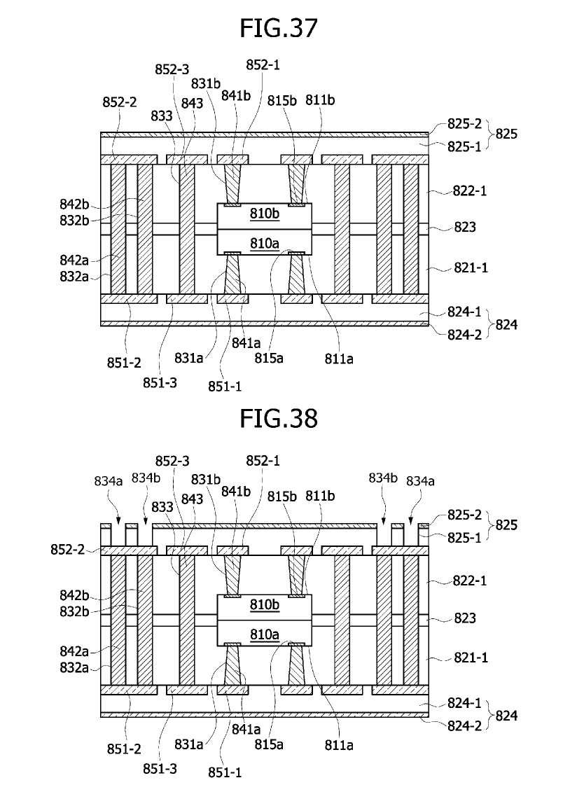

In FIG. 37, a fourth insulation layer 824 may be formed on the insulation body 821-1 of the first insulation layer 821 to cover the first circuit patterns 851-1, 851-2 and 851-3. The fourth insulation layer 824 may be formed of an RCC layer. The fourth insulation layer 824 may be formed to include an insulation body 824-1 comprised of a resin material and a copper layer 824-2 coated on a surface of the insulation body 824-1 opposite to the first insulation layer 821. Accordingly, the insulation body 824-1 of the fourth insulation layer 824 may be attached to the insulation body 821-1 of the first insulation layer 821 exposed between the first circuit patterns 851-1, 851-2 and 851-3.

Similarly, a fifth insulation layer 825 may be formed on the insulation body 822-1 of the second insulation layer 822 to cover the second circuit patterns 852-1, 852-2 and 852-3. The fifth insulation layer 825 may be formed of an RCC layer. The fifth insulation layer 825 may be formed to include an insulation body 825-1 comprised of a resin material and a copper layer 825-2 coated on a surface of the insulation body 825-1 opposite to the second insulation layer 822. Accordingly, the insulation body 825-1 of the fifth insulation layer 825 may be attached to the insulation body 822-1 of the second insulation layer 822 exposed between the second circuit patterns 852-1, 852-2 and 852-3.

In FIG. 38, the fifth insulation layer 825 may be patterned to form via holes 834a and 834b exposing the second circuit patterns 852-2. In various embodiments, the via holes 834a and 834b may be formed to vertically overlap with the first through electrodes 842a and 842b. Although not shown in the cross-sectional view of FIG. 38, additional via holes may also be formed to vertically overlap with the first middle through electrodes 842c. In various other embodiments, the via holes 834a and 834b may be formed not to vertically overlap with the first through electrodes 842a and 842b. In various other embodiments, only the via holes 834a or only the via holes 834b may be formed in the fifth insulation layer 825. The via holes 834a and 834b may be formed using a laser process.

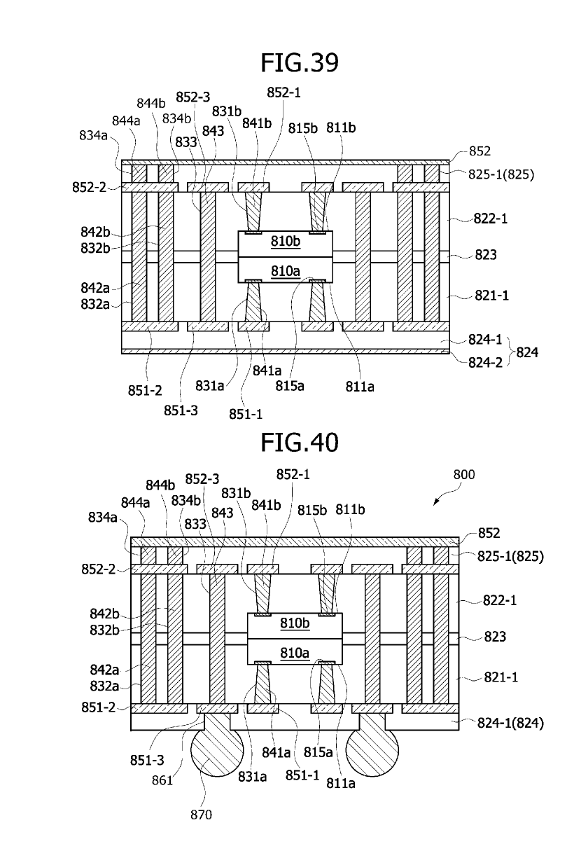

In FIG. 39, a metal layer may be formed to fill the via holes 834a and 834b. Thus, connection vias 844a may be formed in the via holes 834a, and connection vias 844b may be formed in the via holes 834b. In addition, a metal layer 852 may be formed on a top surface of the fifth insulation layer 825. In various embodiments, the connection vias 844a and 844b and the metal layer 852 may be formed using an electroplating process. In such a case, the second circuit patterns 852-2 and the copper layer 825-2 of the fifth insulation layer 825 may be used as seed layers. The connection vias 844a and 844b may electrically couple the second circuit patterns 852-2 to the metal layer 852.

In FIG. 40, the fourth insulation layer 824 may be patterned to form openings 861 that expose the first circuit patterns 851-3. While the openings 861 are formed, the copper layer 824-2 of the fourth insulation layer 824 may be removed. In various embodiments, the copper layer 824-2 may be removed to expose the insulation body 824-1 before forming the openings 861. The insulation body 824-1 may then be patterned to form the openings 861. In various other embodiments, the copper layer 824-2 may be patterned to expose portions of the insulation body 824-1. The exposed portions of the insulation body 824-1 may then be removed to form the openings 861. After the openings 861 are formed, the patterned copper layer 824-2 may be removed.

Subsequently, external connection members 870 such as solder balls may be formed on the fourth insulation layer 824. The solder balls 870 may be formed to contact the first circuit patterns 851-3 through the openings 861. Contact structures between the solder balls 870 and the first circuit patterns 851-3 may be realized to be different according to various embodiments.

At least one of the embedded packages described above may be applied to various electronic systems.

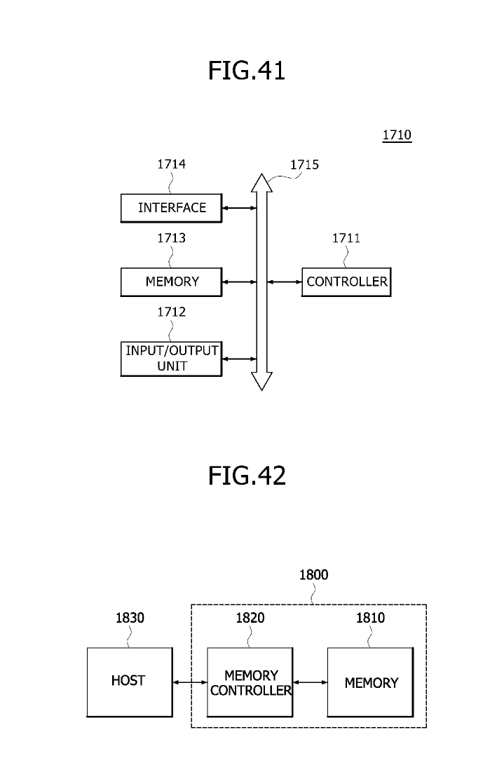

Referring to FIG. 41, the embedded package in accordance with an embodiment may be applied to an electronic system 1710. The electronic system 1710 may include a controller 1711, an input/output unit 1712, and a memory 1713. The controller 1711, the input/output unit 1712 and the memory 1713 may be electrically coupled with one another through a bus 1715 providing a path through which data are transmitted.

For example, the controller 1711 may include at least any one of at least one microprocessor, at least one digital signal processor, at least one microcontroller, and logic devices capable of performing the same functions as these components. At least one of the controller 1711 and the memory 1713 may include at least any one of the embedded packages according to various embodiments of the invention. The input/output unit 1712 may include at least one selected among a keypad, a keyboard, a display device, a touch screen and so forth. The memory 1713 is a device for storing data. The memory 1713 may store data and/or commands to be executed by the controller 1711, and the likes.

The memory 1713 may include a volatile memory device such as a DRAM and/or a nonvolatile memory device such as a flash memory. For example, a flash memory may be mounted to an information processing system such as a mobile terminal or a desk top computer. The flash memory may constitute a solid state disk (SSD). In this case, the electronic system 1710 may stably store a large amount of data in a flash memory system.

The electronic system 1710 may further include an interface 1714 configured to transmit and receive data to and from a communication network. The interface 1714 may be a wired or wireless type. For example, the interface 1714 may include an antenna or a wired or wireless transceiver.

The electronic system 1710 may be realized as a mobile system, a personal computer, an industrial computer or a logic system performing various functions. For example, the mobile system may be any one of a personal digital assistant (PDA), a portable computer, a tablet computer, a mobile phone, a smart phone, a wireless phone, a laptop computer, a memory card, a digital music system and an information transmission/reception system.

Where the electronic system 1710 is an equipment capable of performing wireless communication, the electronic system 1710 may be used in a communication system such as of CDMA (code division multiple access), GSM (global system for mobile communications), NADC (north American digital cellular), E-TDMA (enhanced-time division multiple access), WCDMA (wideband code division multiple access), CDMA2000, LTE (long term evolution) and Wibro (wireless broadband Internet).

Referring to FIG. 42, the embedded package in accordance with various embodiments may be provided in the form of a memory card 1800. For example, the memory card 1800 may include a memory 1810 such as a nonvolatile memory device and a memory controller 1820. The memory 1810 and the memory controller 1820 may store data or read stored data.

The memory 1810 may include at least any one among nonvolatile memory devices to which the packaging technologies of the embodiments of the invention are applied. The memory controller 1820 may control the memory 1810 such that stored data is read out or data is stored according to a read/write request from a host 1830.

The embodiments have been disclosed above for illustrative purposes. Those skilled in the art will appreciate that various modifications, additions and substitutions are possible, without departing from the scope and spirit of the inventive concept as disclosed in the accompanying claims.

What is claimed is:

1. An embedded package comprising:
a chip having a top surface on which a connection member is disposed;
a first insulation layer surrounding a portion of the chip;
a second insulation layer disposed on the first insulation layer so that a bottom surface of the second insulation layer contacts a top surface of the first insulation layer and the second insulation layer covers the chip;
a plurality of circuit patterns disposed on a bottom surface of the first insulation layer;
a third insulation layer disposed on the bottom surface of the first insulation layer to cover the plurality of circuit patterns;
an external connection terminal penetrating the third insulation layer to contact any one of the plurality of circuit patterns;
a metal layer disposed on a top surface of the second insulation layer;
a first via penetrating the first insulation layer to electrically couple the connection member to any one of the circuit patterns; and
a second via penetrating the first and second insulation layers to electrically couple the metal layer to any one of the circuit patterns.

2. The embedded package of claim 1, wherein the chip is disposed to face down so that the top surface of the chip is configured to face downwardly in the first and second insulation layers.

3. The embedded package of claim 1, wherein the first insulation layer surrounds the top surface and sidewalls of the chip.

4. The embedded package of claim 3, wherein the second insulation layer covers a bottom surface of the chip.

5. The embedded package of claim 4, wherein the bottom surface of the chip is substantially coplanar with the top surface of the first insulation layer.

6. The embedded package of claim 1, wherein the first, second and third insulation layers include a same material.

7. The embedded package of claim 6, wherein the first, second and third insulation layers include a resin-coated-copper (RCC) layer.

8. The embedded package of claim 7, wherein the plurality of circuit patterns, the metal layer, the first via and the second via are formed by an electroplating process performed using a copper layer of the RCC layer as a seed layer.

9. The embedded package of claim 1, wherein the second via is disposed to be spaced apart from the chip.

10. An embedded package comprising:
a chip having a top surface on which connection members are disposed;
a first insulation layer surrounding a portion of the chip;
a second insulation layer disposed on the first insulation layer so that a bottom surface of the second insulation layer contacts a top surface of the first insulation layer and the second insulation layer covers the chip;
a plurality of circuit patterns disposed on a bottom surface of the first insulation layer;
a third insulation layer disposed on the bottom surface of the first insulation layer to cover the plurality of circuit patterns;
an external connection terminal penetrating the third insulation layer to contact any one of the plurality of circuit patterns;
a metal layer disposed on a top surface of the second insulation layer;
first vias penetrating the first insulation layer to electrically couple the connection members to the circuit patterns; and
second vias penetrating the first and second insulation layers to electrically couple the metal layer to the circuit patterns,
wherein distances between the second vias and the chip are different.

11. The embedded package of claim 10, wherein the chip is disposed to face down so that the top surface of the chip is configured to face downwardly in the first and second insulation layers.

12. The embedded package of claim 10, wherein the first insulation layer surrounds the top surface and sidewalls of the chip.

13. The embedded package of claim 12, wherein the second insulation layer covers a bottom surface of the chip.

14. The embedded package of claim 13, wherein the bottom surface of the chip is substantially coplanar with the top surface of the first insulation layer.

15. The embedded package of claim 10, wherein the first, second and third insulation layers include a same material.

16. The embedded package of claim 15, wherein the first, second and third insulation layers include a resin-coated-copper (RCC) layer.

17. The embedded package of claim 16, wherein the plurality of circuit patterns, the metal layer, the first vias and the second vias are formed by an electroplating process performed using a copper layer of the RCC layer as a seed layer.

18. The embedded package of claim 10, wherein the second vias includes:
outer vias arrayed on an outer closed loop line which is adjacent to sidewalls of the first and second insulation layers;
inner vias arrayed on an inner closed loop line surrounded by the outer closed loop line and spaced apart from the chip; and
middle vias arrayed on a middle closed loop line between the outer closed loop line and the inner closed loop line,
wherein the outer vias and the middle vias are arrayed in a zigzag fashion along edges of the first and second insulation layers, and
wherein the inner vias and the middle vias are arrayed in a zigzag fashion along the edges of the first and second insulation layers.

19. An embedded package comprising:
a first chip having a top surface on which first connection members are disposed;
a second chip having a top surface on which second connection members are disposed and having a bottom surface to which a bottom surface of the first chip is attached;
a first insulation layer surrounding a portion of the first chip;
a second insulation layer surrounding a portion of the second chip;
a third insulation layer disposed between the first and second insulation layers;
a plurality of first circuit patterns disposed on a bottom surface of the first insulation layer;
a plurality of second circuit patterns disposed on a top surface of the second insulation layer;
a fourth insulation layer disposed on the bottom surface of the first insulation layer to cover the plurality of first circuit patterns;
an external connection terminal penetrating the fourth insulation layer to contact any one of the plurality of first circuit patterns;
a fifth insulation layer disposed on the top surface of the second insulation to cover the plurality of second circuit patterns;
a metal layer disposed on a top surface of the fifth insulation layer;
lower vias penetrating the first insulation layer to electrically couple the first connection members to the first circuit patterns;
upper vias penetrating the second insulation layer to electrically couple the second connection members to the second circuit patterns;
first through electrodes and second through electrodes penetrating the first, second and third insulation layers to electrically couple the first circuit patterns to the second circuit patterns; and
connection vias penetrating the fifth insulation layer to electrically couple the metal layer to the second circuit patterns.

20. The embedded package of claim 19,
wherein the first chip is disposed to face down so that the top surface of the first chip faces downwardly in the first insulation layer; and
wherein the second chip is disposed to face up so that the top surface of the second chip faces upwardly in the second insulation layer.
